(19) United States
(12) Patent Application Publication
(10) Pub. No.: US 2012/0038814 A1
(43) Pub. Date: Feb. 16, 2012

(54) SOLID-STATE IMAGE SENSING DEVICE, METHOD OF MANUFACTURING THE SAME, AND ELECTRONIC APPARATUS

(75) Inventor: Hiroshi Tayanaka, Kanagawa (JP)

(73) Assignee: SONY CORPORATION, Tokyo (JP)

(21) Appl. No.: 13/196,039

(22) Filed: Aug. 2, 2011

(30) Foreign Application Priority Data
Aug. 10, 2010 (JP) 2010-179196

(51) Int. Cl. H04N 5/225; H01L 31/18; H01L 31/0232

(52) U.S. Cl. 348/340; 257/432; 438/69; 257/E31.127; 348/E05.024

(57) ABSTRACT

A solid-state image sensing device includes a plurality of pixels each made up of a photoelectric conversion region and a device to read signal charges from the photoelectric conversion region, and an optical waveguide formed corresponding to the photoelectric conversion region of each pixel, wherein, when viewed in a cross-section along a horizontal plane, the optical waveguide includes an annular core layer having a higher refractive index than a portion surrounding the annular core layer, and a clad layer surrounded by the annular core layer and having a lower refractive index than the annular core layer.

### BACKGROUND

The present technology relates to a solid-state image sensing device, a method of manufacturing the solid-state image sensing device, and an electronic apparatus, such as a camera, including the solid-state image sensing device.

As examples of a solid-state image sensing device (image sensor), there are a CMOS solid-state image sensing device, a CCD solid-state image sensing device, etc. Those solid-state image sensing devices are used in, e.g., various portable terminals including a digital still camera, a digital video camera, a cellular phone with a camera, etc. The CMOS solid-state image sensing device is operated at a lower source voltage than that in the CCD solid-state image sensing device, and hence it is more advantageous from the viewpoint of, e.g., power consumption.

In the CMOS solid-state image sensing device, many unit pixels are two-dimensionally arrayed, and each unit pixel is formed by a photodiode (photoelectric conversion region) serving as a light receiving portion and a plurality of pixel transistors. The plural pixel transistors are usually made up of four transistors, i.e., a transfer transistor, an amplification transistor, a reset transistor, and a selection transistor, or three transistors excepting the selection transistor from the four transistors. Alternatively, a set of those pixel transistors can be used to share a plurality of photodiodes. Terminals of the pixel transistors are connected through multilayer interconnection (wiring) lines so that desired pulse voltages are applied to the plural pixel transistors and signal currents are read from them.

The CCD solid-state image sensing device includes a plurality of photodiodes arrayed two-dimensionally and serving as light receiving portions, a vertical transfer register having the CCD structure and arranged for each column of the light receiving portions, a horizontal transfer register having the CCD structure and arranged at a terminal of the vertical transfer register, and an output portion arranged at a terminal of the horizontal transfer register.

In still another type of solid-state image sensing device, an optical waveguide is formed on a photodiode and incident light having passed through an on-chip lens is introduced to the optical waveguide so that the incident light enters the photodiode with higher efficiency. For example, Japanese Unexamined Patent Application Publication No. 2008-16677 discloses a solid-state image sensing device in which one cylindrical optical waveguide is formed on one photodiode. Japanese Unexamined Patent Application Publication No. 2006-261247 discloses a solid-state image sensing device in which two cylindrical optical waveguides are formed in two stacked stages on one photodiode.

### SUMMARY

When forming the optical waveguide by using a coating material in the solid-state image sensing device, if the opening diameter of the optical waveguide is set larger than a certain size, there is a risk that cracking may occur due to difference in thermal expansion between the coating material forming a core layer and a material forming a clad layer around the core layer. For that reason, it has been regarded as difficult to form the optical waveguide in the solid-state image sensing device having a large pixel size.

For example, in the CMOS solid-state image sensing device where the light receiving portion has a large opening area, an area of a region occupied by the interconnection lines and the pixel transistors is desired to be as small as possible. However, when the area of the region occupied by the interconnection lines and the pixel transistors is reduced, color mixing is more apt to occur with light entering adjacent pixels because the incident light is obliquely scattered. Therefore, an area of a certain size has been necessary for the region occupied by the interconnection lines and the pixel transistors.

When the opening of the optical waveguide is large and the interior of the optical waveguide is made of a single material, the incident light is reflected only at the vicinity of a boundary between a side wall of the optical waveguide and a film on the outer side of the optical waveguide. Because part of the incident light is lost as a component passing through the above-mentioned boundary, the efficiency of collection of the incident light to the photoelectric conversion region is inevitably reduced.

In the CMOS solid-state image sensing device of backside illumination type, for example, although prevention of color mixing is important, the color mixing with the light entering adjacent pixels is apt to occur, and a difficulty resides in reducing the area of the region occupied by the interconnection lines and the pixel transistors.

In consideration of the above-described state of the art, it is desirable to provide a solid-state image sensing device which can prevent cracking in optical waveguides and which can increase the efficiency of light collection. Also, it is desirable to provide a method of manufacturing the solid-state image sensing device, and an electronic apparatus, such as a camera, including the solid-state image sensing device.

A solid-state image sensing device according to an embodiment of the present technology includes a plurality of pixels each made up of a photoelectric conversion region and means for reading signal charges from the photoelectric conversion region, and an optical waveguide formed corresponding to the photoelectric conversion region of each pixel, wherein, when viewed in a cross-section along a horizontal plane, the optical waveguide includes an annular core layer having a higher refractive index than a portion surrounding the annular core layer, and a clad layer surrounded by the annular core layer and having a lower refractive index than the annular core layer.

In the solid-state image sensing device according to the embodiment of the present technology, since the optical waveguide includes the annular core layer and the clad layer surrounded by the annular core layer, the annular core layer has a smaller width in its horizontal cross-section. Therefore, the occurrence of cracking due to thermal expansion inside the optical waveguide can be prevented even when the annular core layer is formed by using a coating material. In the optical waveguide, light incident on the clad layer at the center, which is surrounded by the annular core layer, is reflected at the interface between the clad layer and the core layer, and the reflected light enters the photoelectric conversion region. Other light having passed through the interface between the clad layer and the core layer enters the core layer and further enters the photoelectric conversion region after propagating through the core layer. As a result, a useless light component passing through the interface between the core layer and the portion surrounding the core layer is minimized and the amount of light incident on the photoelectric conversion region is increased.

A method of manufacturing a solid-state image sensing device, according to another embodiment of the present technology, includes forming, on a semiconductor substrate, a plurality of pixels each made up of a photoelectric conversion region and means for reading signal charges from the photoelectric conversion region, forming a recess in a portion of a constituent film formed on one surface of the semiconductor substrate, which portion corresponds to the photoelectric conversion region of each pixel, forming, in the recess, a clad layer that is surrounded by an annular recess when viewed in a cross-section along a horizontal plane, and filling, in the annular recess, a core layer having a higher refractive index than the constituent film present as an outer surrounding portion and than the clad layer, thereby forming an optical waveguide made up of the annular core layer and the clad layer.

In the method of manufacturing the solid-state image sensing device according to the embodiment of the present technology, the optical waveguide is formed by forming the recess in the portion of the constituent film, which portion corresponds to the photoelectric conversion region of each pixel, forming, in the recess, the clad layer that is surrounded by the annular recess, and filling the core layer in the annular recess. Therefore, the annular core layer has a smaller width in its horizontal cross-section, and the occurrence of cracking due to thermal expansion inside the optical waveguide can be prevented even when the annular core layer is formed by using a coating material. Further, since the interface between the core layer and the clad layer on the inner side is formed in addition to the core layer and the constituent film on the outer surrounding side, the optical waveguide can be formed such that a useless light component transmitted to the constituent film on the outer surrounding side is minimized.

An electronic apparatus according to still another embodiment of the present technology includes a solid-state image sensing device, an optical system for introducing incident light to a photoelectric conversion region of the solid-state image sensing device, and a signal processing circuit for processing an output signal of the solid-state image sensing device. The solid-state image sensing device includes a plurality of pixels each made up of a photoelectric conversion region and means for reading signal charges from the photoelectric conversion region, and an optical waveguide formed corresponding to the photoelectric conversion region of each pixel, wherein, when viewed in a cross-section along a horizontal plane, the optical waveguide includes an annular core layer having a higher refractive index than a portion surrounding the annular core layer, and a clad layer surrounded by the annular core layer and having a lower refractive index than the annular core layer.

In the electronic apparatus according to the embodiment of the present technology, since the electronic apparatus includes the solid-state image sensing device including the optical waveguide of the above-mentioned structure, it is possible to prevent the occurrence of cracking due to thermal expansion inside the optical waveguide, to minimize a useless light component transmitted from the interior of the optical waveguide to the outer surrounding portion, and to increase the amount of light incident on the photoelectric conversion region.

With the solid-state image sensing device according to the embodiment of the present technology, the occurrence of cracking in the optical waveguide can be prevented, and the efficiency of light collection to the photoelectric conversion region can be increased.

With the method of manufacturing the solid-state image sensing device according to the embodiment of the present technology, the solid-state image sensing device can be manufactured in which the occurrence of cracking in the optical waveguide is prevented and the efficiency of light collection to the photoelectric conversion region is increased.

With the electronic apparatus according to the embodiment of the present technology, a high-quality electronic apparatus can be provided because the electronic apparatus includes the solid-state image sensing device in which the occurrence of cracking in the optical waveguide is prevented and the efficiency of light collection to the photoelectric conversion region is increased.

### BRIEF DESCRIPTION OF THE DRAWINGS

FIG. 1 illustrates a basic structure of a solid-state image sensing device according to a first embodiment of the present technology;

FIG. 2 is a horizontal sectional view of an optical waveguide in the first embodiment;

FIGS. 3A to 3C are schematic views (No. 1) to explain successive manufacturing steps for main components, the views illustrating an example (1) of a method of manufacturing the solid-state image sensing device according to the first embodiment;

FIGS. 4D to 4F are schematic views (No. 2) to explain the successive manufacturing steps for main components, the views illustrating the example (1) of the method of manufacturing the solid-state image sensing device according to the first embodiment;

FIG. 5 is a schematic view (No. 3) to explain the successive manufacturing steps for main components, the views illustrating the example (1) of the method of manufacturing the solid-state image sensing device according to the first embodiment;

FIGS. 6A to 6C are schematic views (No. 1) to explain successive manufacturing steps for main components, the views illustrating an example (2) of the method of manufacturing the solid-state image sensing device according to the first embodiment;

FIGS. 7D and 7E are schematic views (No. 2) to explain the successive manufacturing steps for main components, the views illustrating the example (2) of the method of manufacturing the solid-state image sensing device according to the first embodiment;

FIGS. 8A to 8C are schematic views (No. 1) to explain successive manufacturing steps for main components, the views illustrating an example (3) of the method of manufacturing the solid-state image sensing device according to the first embodiment;

FIGS. 9D to 9F are schematic views (No. 2) to explain the successive manufacturing steps for main components, the views illustrating the example (3) of the method of manufacturing the solid-state image sensing device according to the first embodiment;

FIG. 10 illustrates a basic structure of a solid-state image sensing device according to a second embodiment of the present technology;

FIG. 11 is a horizontal sectional view of an optical waveguide in the second embodiment;

FIG. 12 illustrates a basic structure of a solid-state image sensing device according to a third embodiment of the present technology;

FIG. 13 is a horizontal sectional view of an optical waveguide in the third embodiment;

FIGS. 14A to 14C are horizontal sectional views illustrating modifications of the optical waveguide, which can be employed in the solid-state image sensing devices according to the embodiments of the present technology;

FIG. 15 illustrates a basic structure of a solid-state image sensing device according to a fourth embodiment of the present technology;

FIG. 16 is a horizontal sectional view of an optical waveguide in the fourth embodiment;

FIGS. 17A to 17C are schematic views (No. 1) to explain successive manufacturing steps for main components, the views illustrating an example (1) of a method of manufacturing the solid-state image sensing device according to the fourth embodiment;

FIGS. 18D and 18E are schematic views (No. 2) to explain the successive manufacturing steps for main components, the views illustrating the example (1) of the method of manufacturing the solid-state image sensing device according to the fourth embodiment;

FIGS. 19A to 19C are schematic views (No. 1) to explain successive manufacturing steps for main components, the views illustrating an example (2) of the method of manufacturing the solid-state image sensing device according to the fourth embodiment;

FIGS. 20D to 20F are schematic views (No. 2) to explain the successive manufacturing steps for main components, the views illustrating the example (2) of the method of manufacturing the solid-state image sensing device according to the fourth embodiment;

FIGS. 21A to 21C are schematic views (No. 1) to explain successive manufacturing steps, the views illustrating a solid-state image sensing device according to a fifth embodiment of the present technology and a method of manufacturing the solid-state image sensing device according to the fifth embodiment;

FIGS. 22D and 22E are schematic views (No. 2) to explain the successive manufacturing steps, the views illustrating the solid-state image sensing device according to the fifth embodiment of the present technology and the method of manufacturing the solid-state image sensing device according to the fifth embodiment;

FIG. 23 illustrates a basic structure of a solid-state image sensing device according to a sixth embodiment of the present technology;

FIG. 24 is a block diagram illustrating an overall configuration of one example of a CMOS solid-state image sensing device that is applied to each of the embodiments of the present technology; and

FIG. 25 illustrates a basic configuration of an electronic apparatus according to a seventh embodiment of the present technology.

### DETAILED DESCRIPTION OF EMBODIMENTS

Embodiments of the present technology will be described below in the following order.

1. Example of overall configuration of CMOS solid-state image sensing device

2. First embodiment (example of structure of solid-state image sensing device and example of method of manufacturing the solid-state image sensing device)

3. Second embodiment (example of structure of solid-state image sensing device)

4. Third embodiment (example of structure of solid-state image sensing device)

5. Fourth embodiment (example of structure of solid-state image sensing device and example of method of manufacturing the solid-state image sensing device)

6. Fifth embodiment (example of structure of solid-state image sensing device and example of method of manufacturing the solid-state image sensing device)

7. Sixth embodiment (example of structure of solid-state image sensing device)

8. Seventh embodiment (example of configuration of electronic apparatus)

### 1. Example of Overall Structure of CMOS Solid-State Image Sensing Device

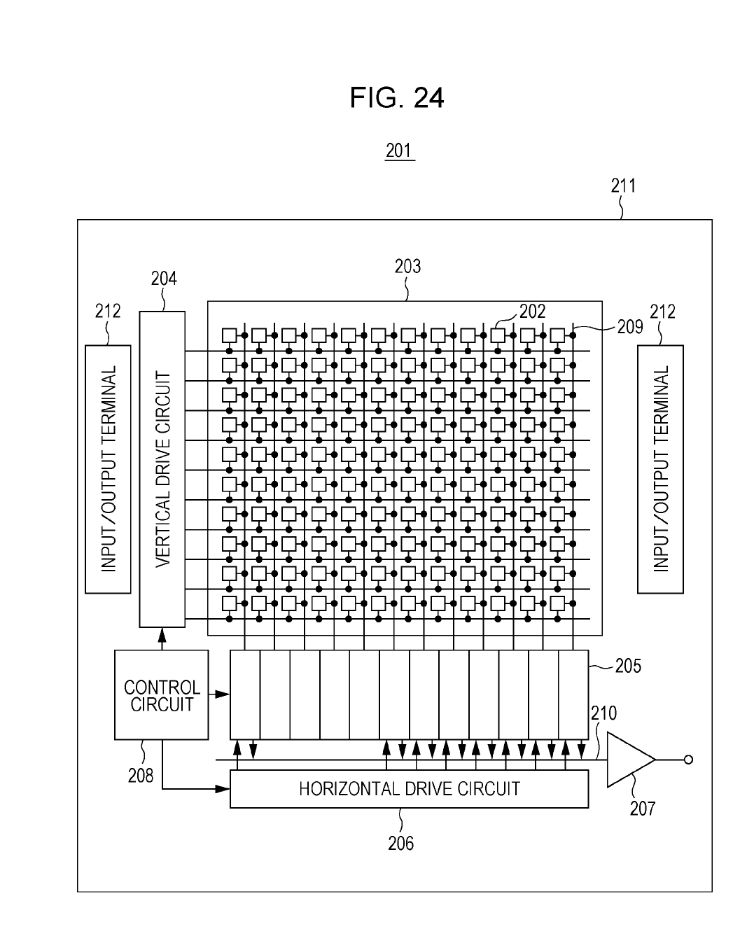

FIG. 24 is a block diagram illustrating an overall configuration of one example of a CMOS solid-state image sensing device that is employed in each of the embodiments of the present technology. As illustrated in FIG. 24, a solid-state image sensing device 201 according to the embodiment includes a pixel region (image sensing region) 203 where a plurality of pixels 202, each including a photoelectric conversion region, are regularly arranged in the form of a two-dimensional array on a semiconductor substrate 211, e.g., a silicon substrate, and a peripheral circuit section. A unit pixel made up of one photoelectric conversion region and a plurality of pixel transistors can be employed as each of the pixels 202. As an alternative, the pixels 202 can be practiced in the so-called sharing-type pixel structure in which plural photoelectric conversion regions share pixel transistors other than a transfer transistor. The plural pixel transistors can be made up of four transistors, i.e., a transfer transistor, a reset transistor, an amplification transistor, and a selection transistor, or three transistors excepting the selection transistor from those four transistors.

The peripheral circuit section is constituted by logic circuits, such as a vertical drive circuit 204, a column signal processing circuit 205, a horizontal drive circuit 206, an output circuit 207, and a control circuit 208.

The control circuit 208 receives an input clock and data for instructing an operation mode, for example, and outputs data such as internal information regarding the solid-state image sensing device. More specifically, in accordance with a vertical synchronizing signal, a horizontal synchronizing signal, and a master clock, the control circuit 208 produces control signals and clock signals, which serve as references for operations of the vertical drive circuit 204, the column signal processing circuit 205, and the horizontal drive circuit 206, etc. The control signals and the clock signals are applied to the vertical drive circuit 204, the column signal processing circuit 205, and the horizontal drive circuit 206, etc.

The vertical drive circuit 204 is constituted by, e.g., a shift register. The vertical drive circuit 204 selects a pixel drive interconnection line and supplies, to the selected pixel drive interconnection line, a pulse for driving the pixels, thereby driving the pixels per line. In other words, the vertical drive circuit 204 sequentially selects and scans the pixels 202 in the pixel region 203 per line in the vertical direction. Further, the vertical drive circuit 204 supplies, to the column signal processing circuit 205, a pixel signal depending on signal charges, which are generated in the photoelectric conversion region, e.g., a photodiode, in each pixel 202 corresponding to the amount of received light, through a vertical signal line 209.

The column signal processing circuit 205 is arranged, for example, per column of the pixels 202, and it executes signal processing, such as noise reduction, per pixel column for signals output from the pixels 202 corresponding to one line. More specifically, the column signal processing circuit 205 executes signal processing, such as CDS (Correlated Double Sampling) to remove fixed pattern noise specific to the pixel 202, signal amplification, and AD conversion. In an output stage of the column signal processing circuit 205, a horizontal selection switch (not shown) is connected between the column signal processing circuit 205 and a horizontal signal line 210.

The horizontal drive circuit 206 is constituted by, e.g., a shift register. The horizontal drive circuit 206 sequentially outputs horizontal scanning pulses to select the column signal processing circuits 205 one by one in a successive manner, thus causing each of the column signal processing circuits 205 to output the pixel signal to the horizontal signal line 210.

The output circuit 207 executes signal processing on signals, which are sequentially supplied from the individual column signal processing circuits 205 through the horizontal signal line 210, and outputs resulting signals. In some cases, the output circuit 207 executes just buffering. In other cases, the output circuit 207 executes adjustment of a black level, correction of column variations, various types of digital signal processing, etc. Input/output terminals 212 allow signals to be transferred from and to the outside.

### 2. First Embodiment

### Example of Structure of Solid-State Image Sensing Device

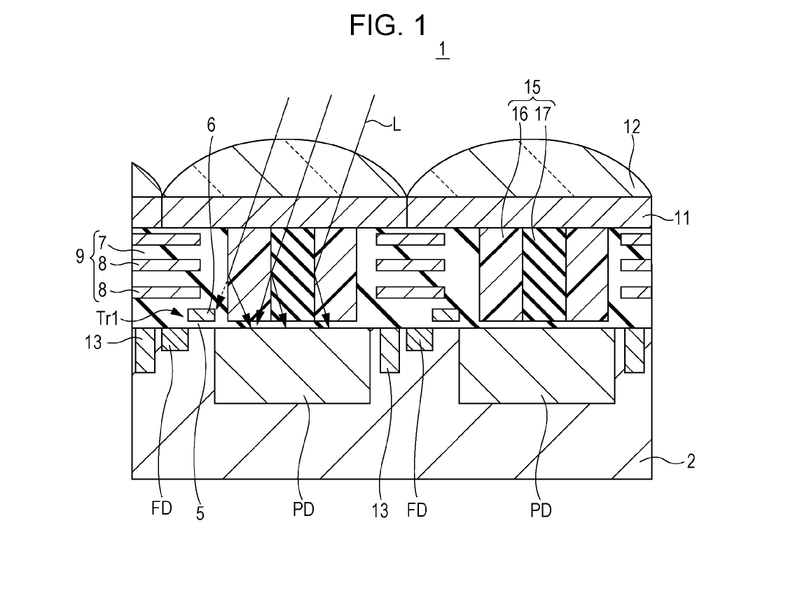

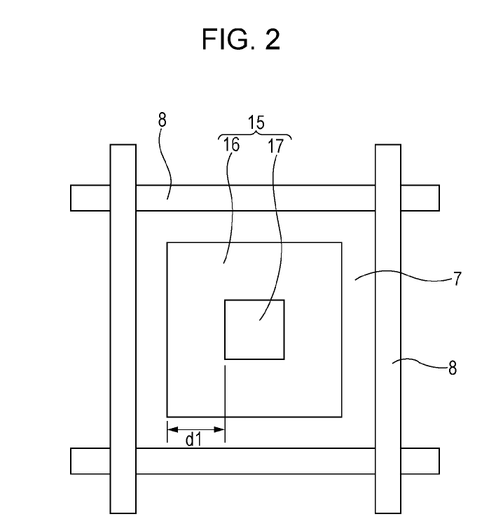

FIGS. 1 and 2 illustrate the solid-state image sensing device according to the first embodiment of the present technology. The first embodiment represents an application to a CMOS solid-state image sensing device of front-side illumination type. The solid-state image sensing device 1 according to the first embodiment includes, on a silicon semiconductor substrate 2, a pixel region where a plurality of pixels, each including a photodiode PD providing a photoelectric conversion region and plural pixel transistors, are regularly arranged in the form of a two-dimensional array. The pixel transistors cooperatively serve as a device to read signal charges from the corresponding photodiode PD. Though not illustrated, the photodiode PD is made up of a charge storage region of first conductivity type, e.g., n-type in this embodiment, where photoelectric conversion and charge storage are performed, and a semiconductor region of second conductivity type, e.g., p-type in this embodiment, which serves to suppress a dark current in its surface. The photodiode PD and the plural pixel transistors are formed in a p-type semiconductor well region, though not shown, which is formed in the semiconductor substrate 2 on the front surface side thereof. In FIG. 1, the plural pixel transistors constituting the pixel are represented by only one, i.e., a transfer transistor Tr1. The transfer transistor Tr1 is made up of the photodiode PD serving as a source, a floating diffusion FD serving as a drain, which is formed by an n-type semiconductor region, and a transfer gate electrode 6 that is formed with a gate insulating film 5 interposed between the transfer gate electrode 6 and the semiconductor substrate 2.

An element separation region 13 for separating the unit pixels from each other is formed in the semiconductor substrate 2. An interconnection (wiring) multilayer 9 including plural layers of interconnection lines 8 with an interlayer insulating film 7 interposed between the adjacent interconnection lines 8 is formed on the front surface of the semiconductor substrate 2. The interconnection lines 8 are each made up of, as described later in detail, a barrier metal layer and an electroconductive layer of copper, which are formed by the damascene process. The interlayer insulating film 7 is formed of, e.g., a silicon oxide (SiO₂) film. On the interconnection multilayer 9, a color filter 11 and an on-chip lens 12 corresponding to each pixel are formed with a flattening film interposed between the color filter 11 and the interconnection multilayer 9.

Further, in the first embodiment, an optical waveguide 15 is formed corresponding to the photodiode PD of each pixel. In more detail, the optical waveguide 15 is formed within the interlayer insulating film 7 of the interconnection multilayer 9 between the color filter 11 and the photodiode PD such that a light emergent end of the optical waveguide 15 is positioned near the photodiode PD. As illustrated in FIG. 2, the optical waveguide 15 is made up of, when viewed in a cross-section along a horizontal plane, an annular core layer 16 having a higher refractive index than that of a portion surrounding the annular core layer 16, i.e., of the interlayer insulating film 7, and a clad layer 17 surrounded by the annular core layer 16 and having a lower refractive index than that of the core layer 16. Stated another way, in the optical waveguide 15 according to the first embodiment, the annular core layer 16 is formed outside the pillar-shaped clad layer 17 so as to surround the latter.

The core layer 16 is preferably formed by coating, e.g., a siloxane-based resin having the refractive index of about 1.7. The clad layer 17 can be formed by using, e.g., a silicon oxide (SiO₂) film having the refractive index of about 1.4. As described above, the interlayer insulating film 7 is formed of, e.g., a silicon oxide (SiO₂) film having the refractive index of about 1.4.

In the solid-state image sensing device 1 according to the first embodiment, as illustrated in FIG. 1, incident light L passes through the on-chip lens 12 and enters the optical waveguide 15. The light L incident on the annular core layer 16 of the optical waveguide 15 enters the photodiode PD after propagating through the interior of the core layer 16 and after being reflected at the interface between the core layer 16 and the clad layer 17 and at the interface between the core layer 16 and the interlayer insulating film 7. The light L incident on the central clad layer 17 of the optical waveguide 15 enters the photodiode PD in some part thereof after being reflected at the interface between the clad layer 17 and the core layer 16, and in the other part thereof after passing from the clad layer 17 to the core layer 16 and then propagating through the interior of the core layer 16.

With the solid-state image sensing device 1 according to the first embodiment, since the core layer 16 of the optical waveguide 15 is formed in an annular pattern, an opening width d1 of the core layer 16 through which the light is primarily guided can be reduced. In other words, the opening width d1 of the core layer 16 can be made smaller than a certain value. As a result, when the core layer 16 is formed by using a coating material, e.g., a siloxane-based resin, a shrinkage rate of the core layer 16 can be so reduced as to prevent the occurrence of cracking due to stresses generated between the core layer 16 and the clad layer 17 with thermal expansion. The optical waveguide 15 according to the first embodiment is preferably applied, in particular, to an optical waveguide for use in a solid-state image sensing device having a large pixel size.

In the optical waveguide 15 having the annular core layer 16, because of having the interface between the core layer 16 and the interlayer insulating film 7 around the core layer 16 and the interface between the core layer 16 and the clad layer 17 positioned inside the core layer 16, the number of the interfaces is increased in comparison with that in the related-art optical waveguides. With such an arrangement, since the number of locations at which the incident light is reflected is increased, it is possible to reduce a component of light transmitted to the outside of the optical waveguide and hence to reduce the loss of light. In addition, both refracted and transmitted light components can be guided so as to reach the photodiode PD in a larger amount. Further, even in the case of oblique incident light, a light component capable of reaching the photodiode PD can be increased by increasing the number of light reflections. Consequently, the efficiency of light collection to the photodiode PD can be increased.

Since the incident light can be guided by the optical waveguide 15 to the photodiode PD with higher efficiency, color mixing can be avoided in the solid-state image sensing device having a large pixel size even when the area occupied by the interconnection lines and the pixel transistors is reduced. With the reduction in the area occupied by the interconnection lines and the pixel transistors, the area of the photodiode PD can be increased and hence a sensitivity characteristic of the solid-state image sensing device can be improved.

### Example (1) of Method of Manufacturing Solid-State Image Sensing Device

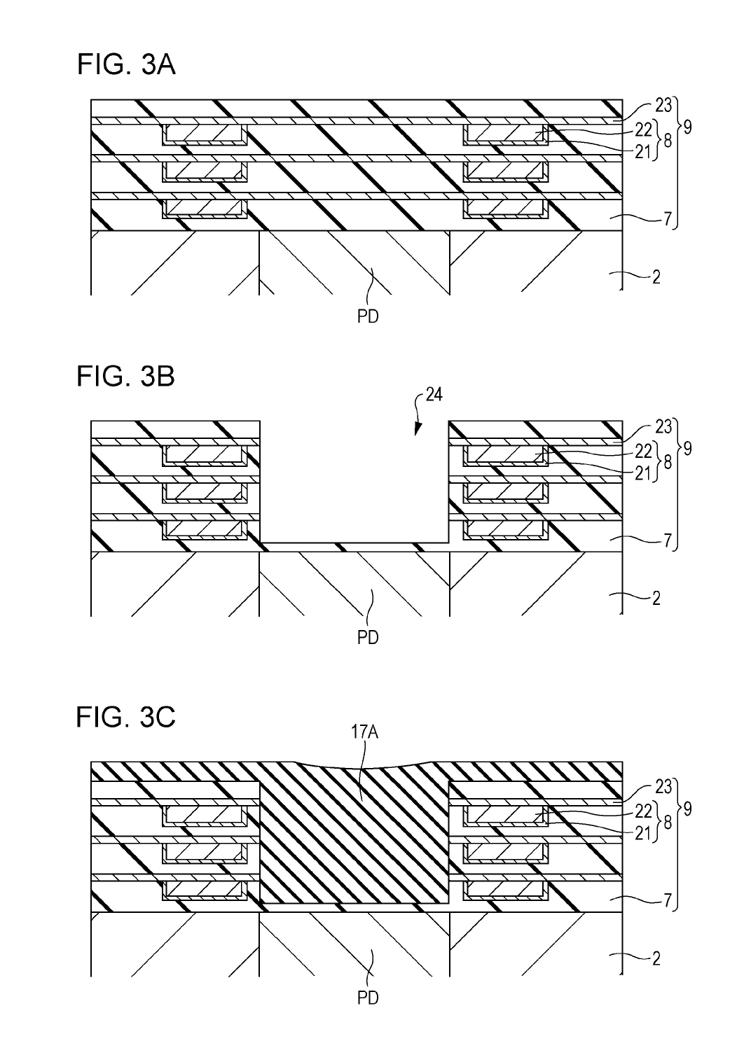

FIGS. 3A to 5 illustrate an example (1) of the method of manufacturing the solid-state image sensing device 1 according to the first embodiment. As illustrated in FIG. 3A, the pixel made up of the photodiode PD and the pixel transistors (not shown), and the element separation region (not shown) are formed in the silicon semiconductor substrate 2 on the front surface side thereof, and the interconnection multilayer 9 is formed on the front surface of the semiconductor substrate 2. In the interconnection multilayer 9, the interconnection lines 8 are each formed by a barrier metal layer 21 and an electroconductive layer 22 of copper by the damascene process such that the barrier metal layer 21 and the electroconductive layer 22 are buried in the interlayer insulating film 7 formed of, e.g., a silicon oxide (SiO₂) film. Further, a diffusion prevention layer 23 is formed to cover respective upper surfaces of the interconnection lines 8. Multiple layers of the interconnection lines 8 are formed by repeating the above-described steps. The interconnection multilayer 9, specifically, the interlayer insulating film 7 in the interconnection multilayer 9, serves as a constituent film (that defines an optical path length).

Next, as illustrated in FIG. 3B, the interlayer insulating film 7 and the diffusion prevention film 23 are selectively etched away in a portion of the interconnection multilayer 9 corresponding to each of the photodiodes PD, thereby forming a recess 24 substantially in the interlayer insulating film 7. The recess 24 is formed such that its bottom surface is positioned as close as possible to the photodiode PD.

Next, as illustrated in FIG. 3C, for example, a silicon oxide (SiO₂) film 17A having the refractive index of about 1.4 and becoming the clad layer is deposited on an entire surface of the interconnection multilayer 9 so as to fill the recess 24. The silicon oxide film 17A can be formed, for example, by the CVD (Chemical Vapor Deposition) process.

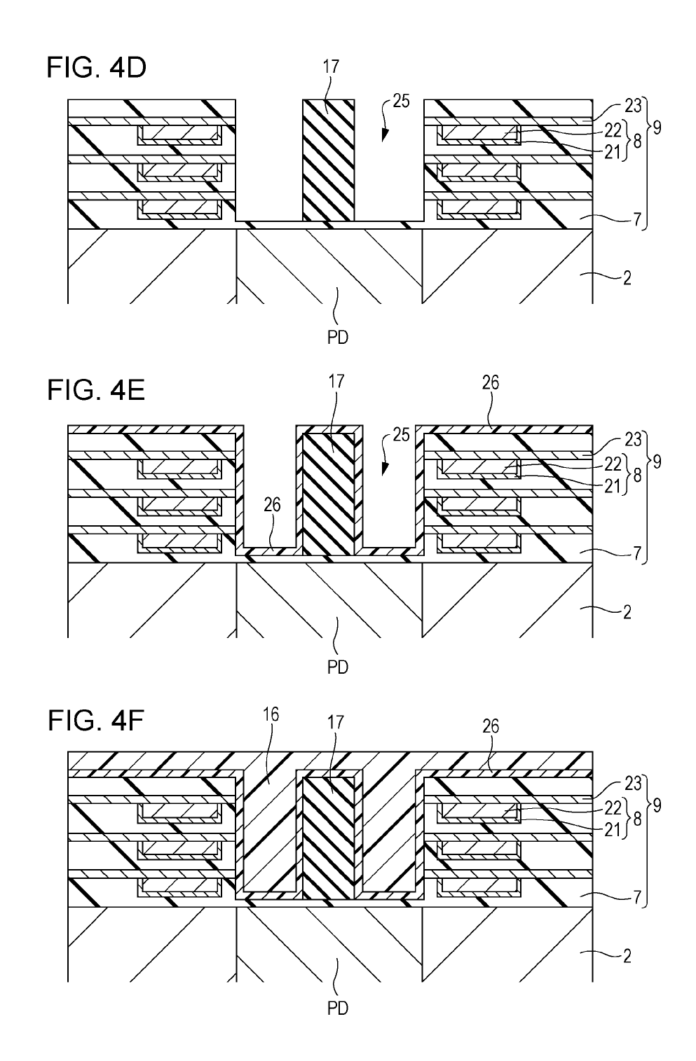

Next, as illustrated in FIG. 4D, the silicon oxide film 17A is patterned by using the photolithography technique and the etching technique to form the clad layer 17 at a center in the recess 24 such that an upper surface of the clad layer 17 is flush with the upper surface of the interconnection multilayer 9. With the formation of the clad layer 17, an annular recess 25 is formed within the recess 24 in a surrounding relation to the clad layer 17. Stated another way, the clad layer 17 surrounded by the annular recess 25 is formed within the recess 24 when viewed in a cross-section along a horizontal plane.

Next, as illustrated in FIG. 4E, a passivation film 26 is formed all over an inner wall surface of the annular recess 25, an upper surface of the clad layer 17, and the upper surface of the interconnection multilayer 9. The passivation film 26 is made compatible with a siloxane-based resin, which is used to form the core layer later, to ensure satisfactory adhesion of the core layer with respect to the inner wall surface of the annular recess 25. The passivation film 26 constitutes a part of the core layer, and it is made of, e.g., a silicon nitride (SiN) film having the refractive index of about 2.0, which is higher than that of the core layer.

Next, as illustrated in FIG. 4F, the siloxane-based resin, for example, is coated all over the clad layer 17 and the interconnection multilayer 9, including an inner space of the annular recess 25. The core layer 16 having an annular shape is formed by the siloxane-based resin that has been filled in the annular recess 25.

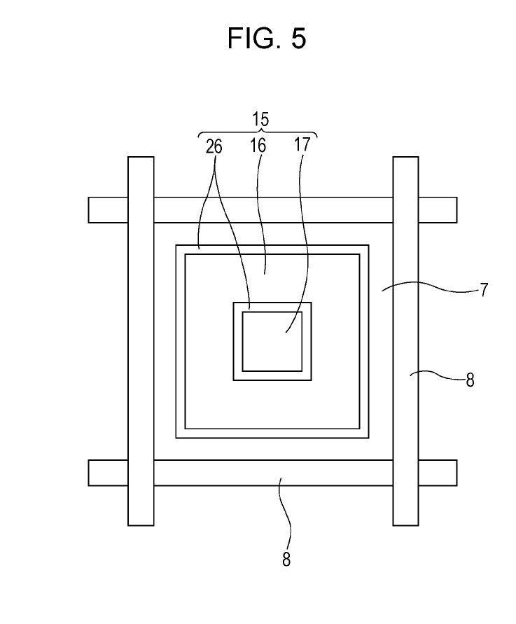

Through the above-described steps, as illustrated in FIG. 5, the optical waveguide 15 is formed which is made up of, when viewed in a cross-section along a horizontal plane, the pillar-shaped clad layer 17 positioned at a center and the annular core layer 16 surrounding the clad layer 17. Further, the optical waveguide 15 of this example includes the passivation film 26, which is formed along outer and inner peripheries of the core layer 16, which constitutes a part of the core layer 16, and which has a higher refractive index than the core layer 16.

Thereafter, the color filter and the on-chip lens are formed on the flattened siloxane-based resin layer, whereby the CMOS solid-state image sensing device 1 of front-side illumination type, including the optical waveguide 15, is obtained.

### Example (2) of Method of Manufacturing Solid-State Image Sensing Device

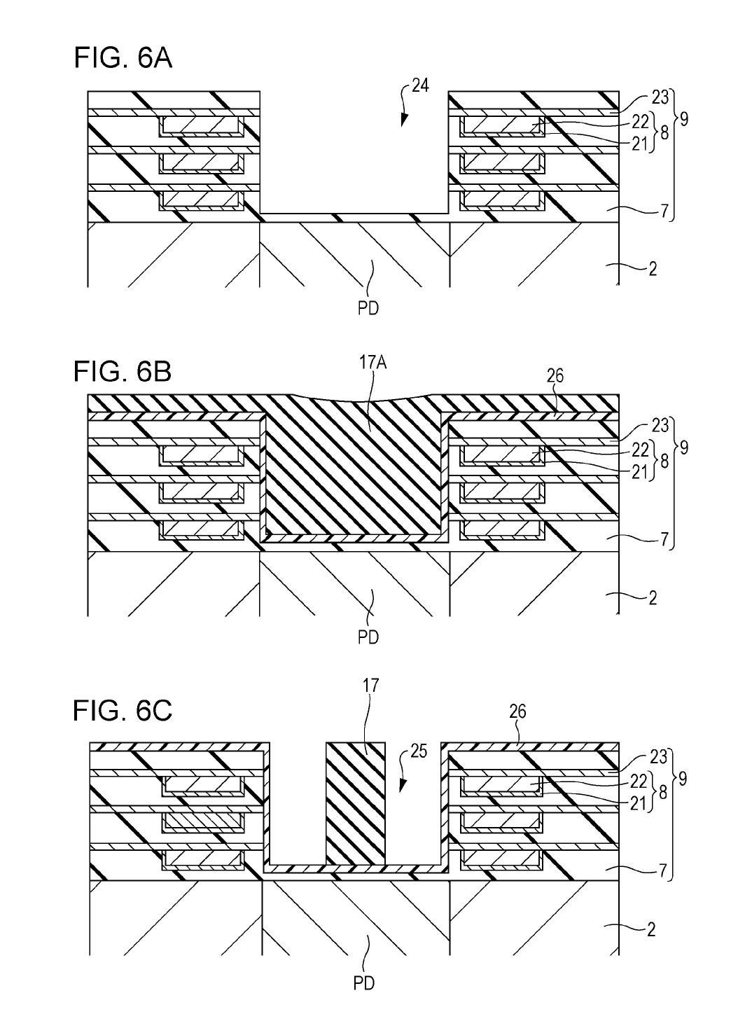

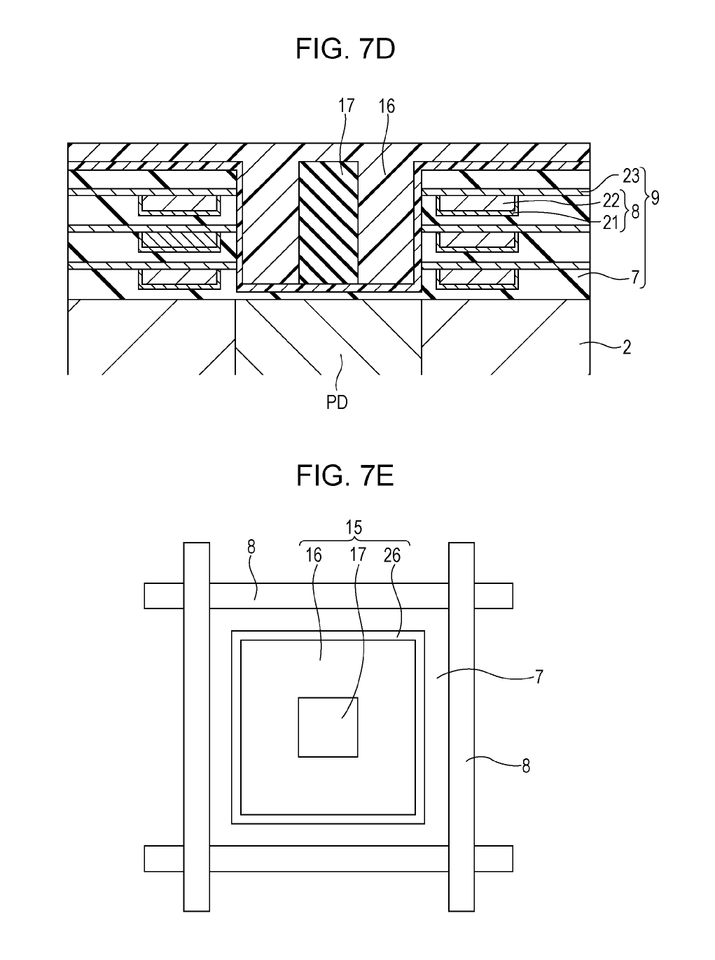

FIGS. 6A to 7E illustrate an example (2) of the method of manufacturing the solid-state image sensing device 1 according to the first embodiment. In this example, as in the above-described step illustrated in FIG. 3A, the pixel made up of the photodiode PD and the pixel transistors, and the element separation region are formed in the silicon semiconductor substrate 2. Further, the interconnection multilayer 9 including the multiple layers of the interconnection lines 8 with the interlayer insulating film 7 interposed between the adjacent interconnection lines 8 is formed on the front surface of the semiconductor substrate 2 by the damascene process.

Next, as in the above-described step illustrated in FIG. 3B, the interlayer insulating film 7 and the diffusion prevention film 23 are selectively etched away in a portion of the interconnection multilayer 9 corresponding to each of the photodiodes PD, as illustrated in FIG. 6A, thereby forming a recess 24 substantially in the interlayer insulating film 7. The recess 24 is formed such that its bottom surface is positioned as close as possible to the photodiode PD.

Next, as illustrated in FIG. 6B, a passivation film 26 made of, e.g., a silicon nitride (SiN) film having the refractive index of about 2.0 is formed all over an inner wall surface of the recess 24 and a surface of the interconnection multilayer 9. Then, for example, a silicon oxide (SiO₂) film 17A having the refractive index of about 1.4 and becoming the clad layer is deposited on the passivation film 26 so as to fill the recess 24. The silicon oxide film 17A can be formed, for example, by the CVD (Chemical Vapor Deposition) process.

Next, as illustrated in FIG. 6C, the silicon oxide film 17A is patterned by using the photolithography technique and the etching technique to form the clad layer 17 at a center in the recess 24 such that an upper surface of the clad layer 17 is flush with an upper surface of the passivation film 26 on the interconnection multilayer 9. With the formation of the clad layer 17, an annular recess 25 is formed within the recess 24 in a surrounding relation to the clad layer 17. Stated another way, the clad layer 17 surrounded by the annular recess 25 is formed within the recess 24 when viewed in a cross-section along a horizontal plane.

Next, as illustrated in FIG. 7D, the siloxane-based resin, for example, is coated all over the clad layer 17 and the interconnection multilayer 9, including an inner space of the annular recess 25. The core layer 16 having an annular shape is formed by the siloxane-based resin that has been filled in the annular recess 25.

Through the above-described steps, as illustrated in FIG. 7E, the optical waveguide 15 is formed which is made up of, when viewed in a cross-section along a horizontal plane, the pillar-shaped clad layer 17 positioned at a center and the annular core layer 16 surrounding the clad layer 17. Further, the optical waveguide 15 of this example includes the passivation film 26, which is formed along an outer periphery of the core layer 16, which constitutes a part of the core layer 16, and which has a higher refractive index than the core layer 16.

Thereafter, the color filter and the on-chip lens are formed on the flattened siloxane-based resin layer, whereby the CMOS solid-state image sensing device 1 of front-side illumination type, including the optical waveguide 15, is obtained.

### Example (3) of Method of Manufacturing Solid-State Image Sensing Device

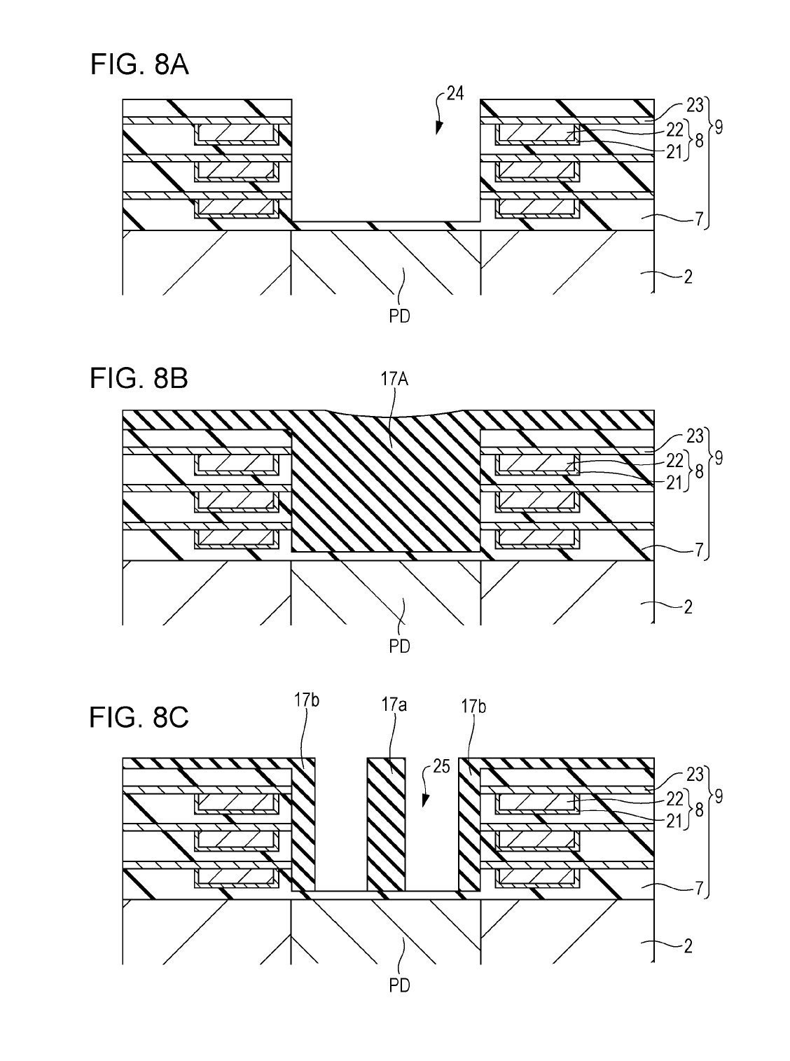

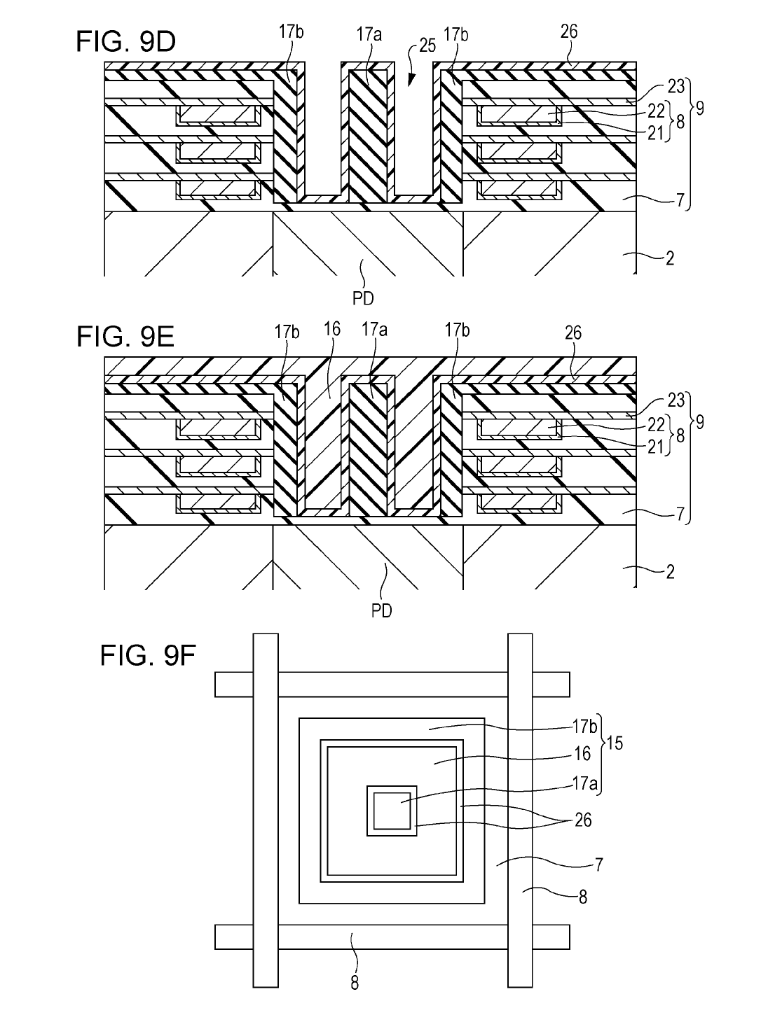

FIGS. 8A to 9F illustrate an example (3) of the method of manufacturing the solid-state image sensing device 1 according to the first embodiment. In this example, as in the above-described step illustrated in FIG. 3A, the pixel made up of the photodiode PD and the pixel transistors, and the element separation region are formed in the silicon semiconductor substrate 2. Further, the interconnection multilayer 9 including the multiple layers of the interconnection lines 8 with the interlayer insulating film 7 interposed between the adjacent interconnection lines 8 is formed on the front surface of the semiconductor substrate 2 by the damascene process.

Next, as in the above-described step illustrated in FIG. 3B, the interlayer insulating film 7 and the diffusion prevention film 23 are selectively etched away in a portion of the interconnection multilayer 9 corresponding to each of the photodiodes PD, as illustrated in FIG. 8A, thereby forming a recess 24 substantially in the interlayer insulating film 7. The recess 24 is formed such that its bottom surface is positioned as close as possible to the photodiode PD.

Next, as illustrated in FIG. 8B, for example, a silicon oxide (SiO₂) film 17A having the refractive index of about 1.4 and becoming the clad layer is deposited on an entire surface of the interconnection multilayer 9 so as to fill the recess 24. The silicon oxide film 17A can be formed, for example, by the CVD (Chemical Vapor Deposition) process.

Next, as illustrated in FIG. 8C, the silicon oxide film 17A is patterned by using the photolithography technique and the etching technique to form a clad layer 17a and a clad layer 17b respectively in a central area of the recess 24 and a peripheral area surrounding the recess 24. The clad layer 17b in the peripheral area is formed so as to extend over the entire surface of the interconnection multilayer 9. Between the clad layers 17a and 17b, an annular recess 25 is formed in a surrounding relation to the clad layer 17a. Stated another way, the annular recess 25 surrounded by the clad layer 17b in the peripheral area and the clad layer 17a surrounded by the annular recess 25 are formed within the recess 24 when viewed in a cross-section along a horizontal plane.

Next, as illustrated in FIG. 9D, a passivation film 26 is formed all over respective surfaces of the clad layers 17a and 17b, including an inner wall surface of the annular recess 25. The passivation film 26 is made compatible with a siloxane-based resin, which is used to form the core layer later, to ensure satisfactory adhesion of the core layer with respect to the inner wall surface of the annular recess 25. The passivation film 26 constitutes a part of the core layer 16, and it is made of, e.g., a silicon nitride (SiN) film having the refractive index of about 2.0, which is higher than that of the core layer.

Next, as illustrated in FIG. 9E, the siloxane-based resin, for example, is coated all over the clad layers 17a and 17b, including an inner surface of the annular recess 25. The core layer 16 having an annular shape is formed by the siloxane-based resin that has been filled in the annular recess 25.

Through the above-described steps, as illustrated in FIG. 9F, the optical waveguide 15 is formed which is made up of, when viewed in a cross-section along a horizontal plane, the pillar-shaped clad layer 17a positioned at a center, the annular core layer 16 surrounding the clad layer 17a, and the annular clad layer 17b surrounding the core layer 16. Further, the optical waveguide 15 of this example includes the passivation film 26, which is formed along outer and inner peripheries of the core layer 16, which constitutes a part of the core layer 16, and which has a higher refractive index than the core layer 16.

Thereafter, the color filter and the on-chip lens are formed on the flattened siloxane-based resin layer, whereby the CMOS solid-state image sensing device 1 of front-side illumination type, including the optical waveguide 15, is obtained.

With the above-described examples (1) to (3) of the method of manufacturing the solid-state image sensing device 1, it is possible to manufacture the solid-state image sensing device 1 including the optical waveguide 15 of such a basic structure that the annular core layer 16 is formed in a surrounding relation to the pillar-shaped clad layer 17 (17a) at the center. In other words, the optical waveguide 15 is formed by forming the recess in a portion of the interconnection multilayer 9, which corresponds to the photodiode PD of each pixel, forming the clad layer 17 within the recess 24 in a state surrounded by the annular recess 25, and filling the core layer 16 in the annular recess 25. Accordingly, the core layer 16 has a smaller width in its horizontal cross-section, and the occurrence of cracking due to thermal expansion inside the optical waveguide 15 can be prevented even when the core layer 16 is formed by using a coating material. Further, since the interface between the core layer 16 and the clad layer 17 positioned inside the core layer 16 is formed in addition to the interface between the core layer 16 and the interlayer insulating film 7 surrounding the core layer 16, the optical waveguide is formed such that a useless light component transmitted to the interlayer insulating film 7 on the outer peripheral side can be minimized.

Further, since the siloxane-based resin becoming the core layer 16 is filled in the annular recess 25 after forming the passivation film 26 made of the silicon nitride film on the inner wall surface of the annular recess 25, adhesion of the core layer 16 in the annular recess 25 with respect to the inner wall surface of the annular recess 25 is obtained at a satisfactory level.

### 3. Second Embodiment

### Example of Structure of Solid-State Image Sensing Device

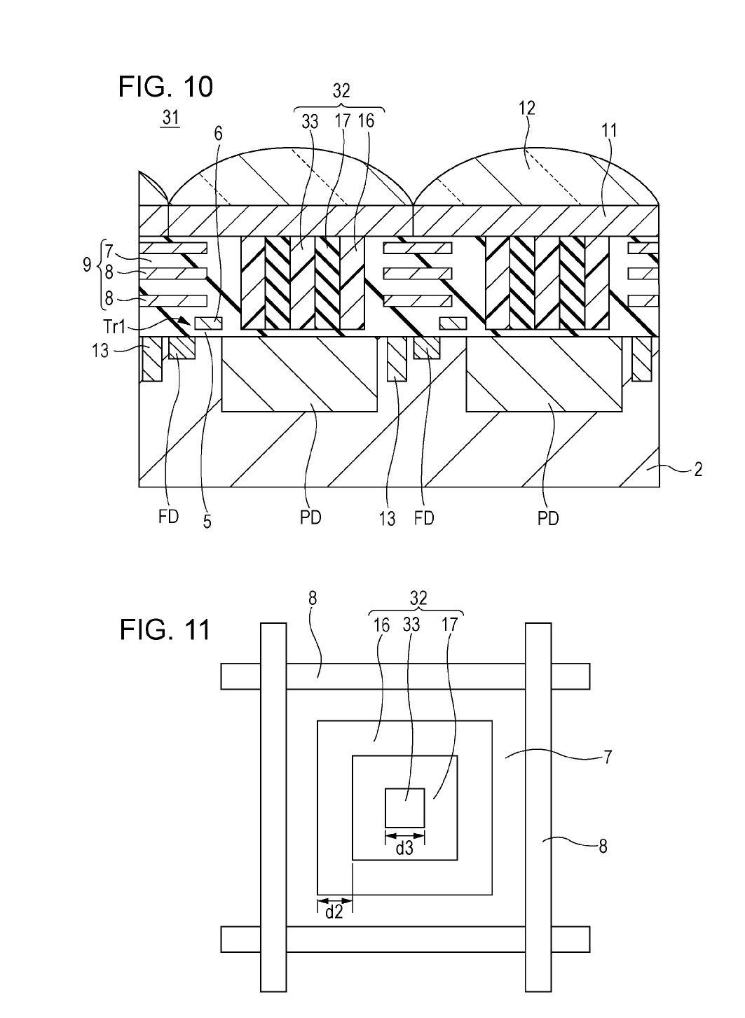

FIGS. 10 and 11 illustrate the solid-state image sensing device according to the second embodiment of the present technology. The second embodiment represents an application to a CMOS solid-state image sensing device of front-side illumination type. The solid-state image sensing device 31 according to the second embodiment includes, in particular, an optical waveguide 32 that is formed corresponding to the photodiode PD of each pixel and that is made up of an annual core layer 16, a clad layer 17 surrounded by the annual core layer 16, and a central core layer 33 surrounded by the clad layer 17. Stated another way, the optical waveguide 32 includes, in a concentric relation when viewed in a cross-section along a horizontal plane, the annular core layer 16 having a higher refractive index than the interlayer insulating film 7 surrounding the annular core layer 16, the clad layer 17 surrounded by the annual core layer 16 and having a lower refractive index than the annual core layer 16, and the central core layer 33 having a pillar-like shape and positioned at a center of the clad layer 17. The central core layer 33 is made of a material having a higher refractive index than the clad layer 17. In this example, the annual core layer 16 and the central core layer 33 are made of the same material, e.g., a siloxane-based resin. The clad layer 17 is made of, e.g., a silicon oxide film as in the above-described example.

Because the remaining structure is similar to that described above in connection with the first embodiment, components in FIGS. 10 and 11 corresponding to those in FIGS. 1 and 2 are denoted by the same reference symbols and duplicate description of those components is omitted.

The solid-state image sensing device 31 according to the second embodiment can be manufactured by employing the above-described example (1) or (2) of the manufacturing method according to the first embodiment except for that a pattern having an annular recess and a central recess positioned at a center of the former is formed in the step of patterning the silicon oxide film 17A.

With the solid-state image sensing device 31 according to the second embodiment, since the optical waveguide 32 includes the annular core layer 16 and the pillar-shaped core layer 33 at the center of the clad layer 17 surrounded by the annular core layer 16, respective opening widths d2 and d3 of the core layers 16 and 33 can be each reduced. Therefore, when the core layer 16 (33) is formed by using a coating material, e.g., the siloxane-based resin, a shrinkage rate of the core layer 16 (33) can be further reduced, and the occurrence of cracking due to thermal expansion can be prevented. The optical waveguide 32 according to the second embodiment is preferably applied, in particular, to the optical waveguide in the solid-state image sensing device having a large pixel size. Further, since the optical waveguide 32 provides a larger number of reflection interfaces, a light loss can be further reduced and the efficiency of light collection to the photodiode PD can be further increased.

In addition, the second embodiment also has the same advantages as those described above in connection with the first embodiment.

### 4. Third Embodiment

### Example of Structure of Solid-State Image Sensing Device

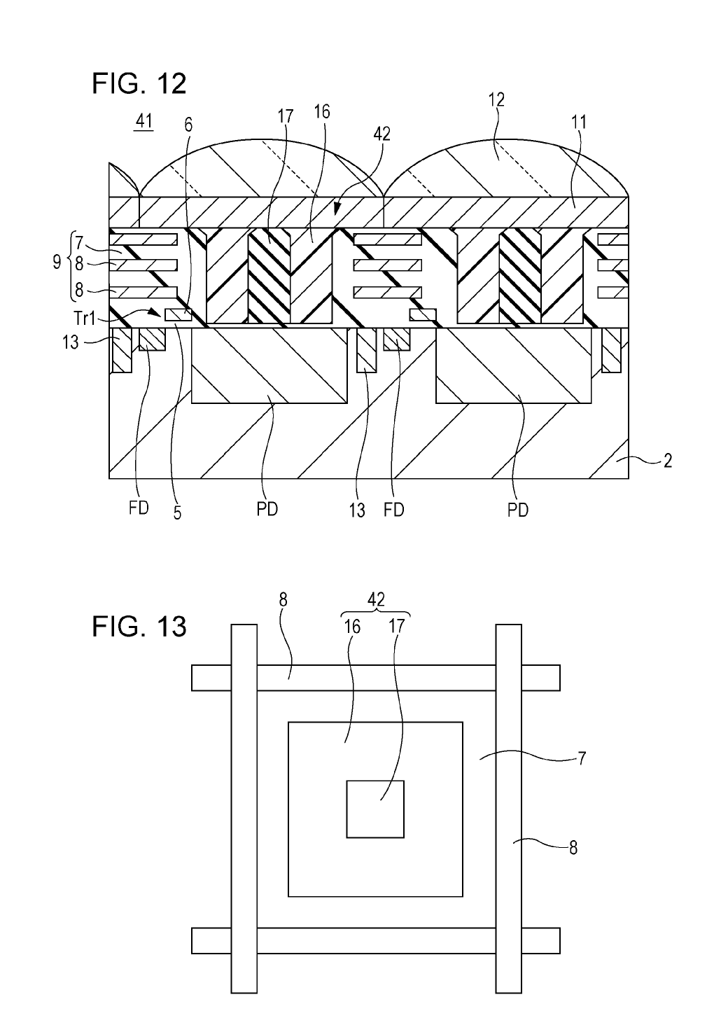

FIGS. 12 and 13 illustrate the solid-state image sensing device according to the third embodiment of the present technology. The third embodiment represents an application to a CMOS solid-state image sensing device of front-side illumination type. The solid-state image sensing device 41 according to the third embodiment includes, in particular, an optical waveguide 42 that is formed corresponding to the photodiode PD of each pixel and that is made up of an annual core layer 16 and a clad layer 17 surrounded by the annual core layer 16. Further, the annular core layer 16 has a widened opening end on the light incident side.

Because the remaining structure is similar to that described above in connection with the first embodiment, components in FIGS. 12 and 13 corresponding to those in FIGS. 1 and 2 are denoted by the same reference symbols and duplicate description of those components is omitted.

With the solid-state image sensing device 41 according to the third embodiment, since the optical waveguide 42 includes the annular core layer 16 having the widened opening end on the light incident side, the incident light can be more easily guided to the optical waveguide 42. Therefore, the efficiency of light collection to the photodiode PD can be further increased, thus providing higher sensitivity. Further, as in the first embodiment, the occurrence of cracking due to thermal expansion inside the optical waveguide 42 can be prevented.

In addition, the third embodiment also has the same advantages as those described above in connection with the first embodiment.

### Modified Examples of Structure of Optical Waveguide

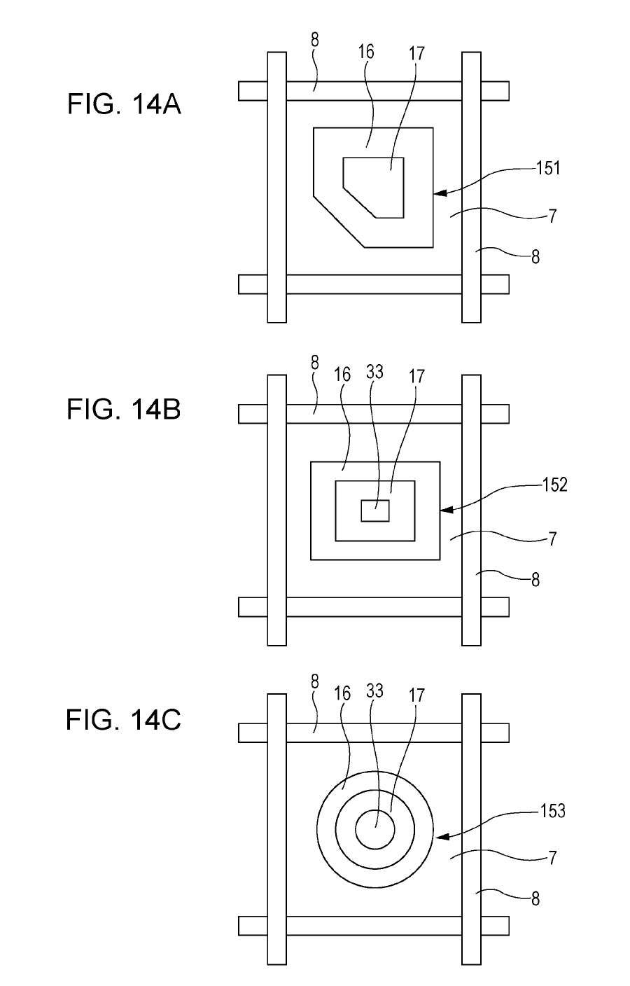

FIGS. 14A to 14C illustrate modified examples of the optical waveguide, which can be employed in the solid-state image sensing devices according to the embodiments of the present technology. Each of FIGS. 14A to 14C represents the shape of the optical waveguide when viewed in a horizontal cross-section.

An optical waveguide 151 illustrated in FIG. 14A is a modification of the optical waveguide 15 illustrated in FIG. 2. In the optical waveguide 151, an annual core layer 16 surrounding a clad layer 17 is formed in a polygonal shape in match with the shape of the pixel. The optical waveguide 151 including the polygonal core layer 16 can be applied to the so-called sharing-type pixel structure, e.g., a later-described sharing-type structure in unit of four pixels.

An optical waveguide 152 illustrated in FIG. 14B is similar to the optical waveguide 32 illustrated in FIG. 11. The optical waveguide 152 is made up of an annual core layer 16 positioned on the outer side, a clad layer 17, and a pillar-shaped core layer 33 positioned on the inner side, those layers being concentrically arranged in rectangular shape.

An optical waveguide 153 illustrated in FIG. 14C is a modification of the optical waveguide 32 illustrated in FIG. 11. The optical waveguide 153 is made up of an annual core layer 16 positioned on the outer side, a clad layer 17, and a pillar-shaped core layer 33 positioned on the inner side, those layers being concentrically arranged in circular shape.

While, in the above-described method of manufacturing the solid-state image sensing device, the passivation film 26 is formed along both the outer periphery and the inner periphery of the annular core layer 16 (see FIGS. 5 and 9F) or along only the outer periphery of the annular core layer 16 (see FIG. 7E) when viewed in a horizontal cross-section, the passivation film 26 may be formed along only the inner periphery of the annular core layer 16.

### 5. Fourth Embodiment

### Example of Structure of Solid-State Image Sensing Device

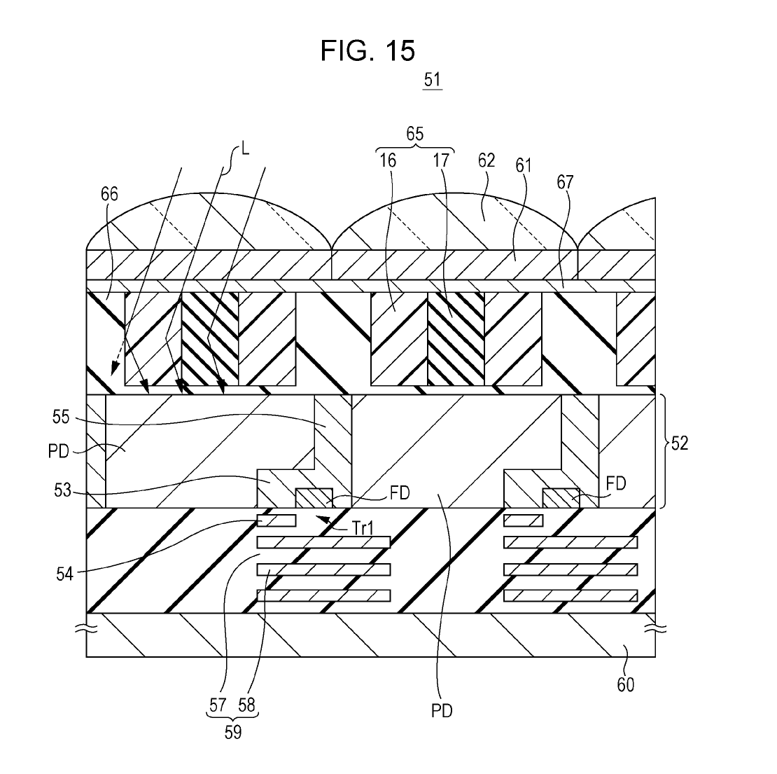

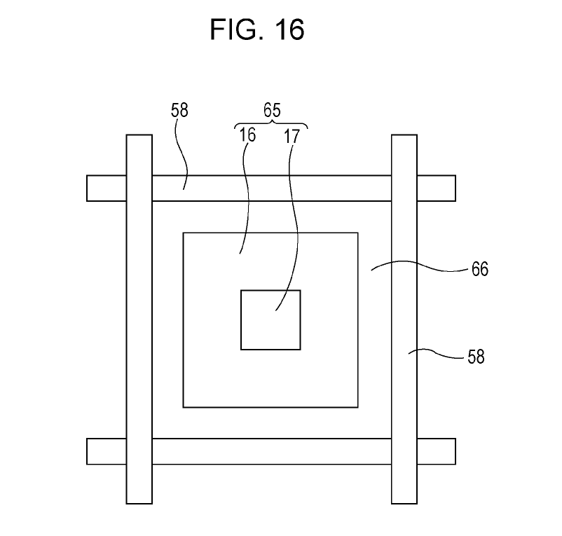

FIGS. 15 and 16 illustrate the solid-state image sensing device according to the fourth embodiment of the present technology. The fourth embodiment represents an application to a CMOS solid-state image sensing device of backside illumination type. The solid-state image sensing device 51 according to the fourth embodiment includes, on a silicon semiconductor substrate 52 polished for thinning thereof, a pixel region where a plurality of pixels, each including a photodiode PD providing a photoelectric conversion region and plural pixel transistors, are regularly arranged in the form of a two-dimensional array. The photodiode PD is formed to fully extend through the semiconductor substrate 52 in the direction of depth thereof and, though not illustrated, it is made up of a charge storage region of first conductivity type, e.g., n-type in this embodiment, where photoelectric conversion and charge storage are performed, and semiconductor regions of second conductivity type, e.g., p-type in the first embodiment, which serve to suppress a dark current in front and back surfaces thereof. The photodiode PD is formed to extend backward of the plural pixel transistors. The plural pixel transistors are formed in a p-type semiconductor well region 53, which is formed in the semiconductor substrate 52 on the front surface side thereof. In FIG. 15, the plural pixel transistors are represented by only one, i.e., a transfer transistor Tr1. The transfer transistor Tr1 is made up of the photodiode PD serving as a source, a floating diffusion FD serving as a drain, which is formed by an n-type semiconductor region, and a transfer gate electrode 54 that is formed with a gate insulating film interposed between the transfer gate electrode 54 and the semiconductor substrate 52. A p-type semiconductor layer, for example, which serves as an element separation region 55, is formed between adjacent pixels.

An interconnection (wiring) multilayer 59 including plural layers of interconnection lines 58 with an interlayer insulating film 57 interposed between the adjacent interconnection lines 58 is formed on the front surface of the semiconductor substrate 52, and a support substrate 60 is bonded onto the interconnection multilayer 59. There are no limitations on layout of the interconnection lines 8, and the interconnection lines 58 are formed in a partly overlapped relation to the photodiode PD. The back surface of the semiconductor substrate 52 on the side oppositely away from the interconnection multilayer 59 serves as a light receiving surface. A color filter 61 and an on-chip lens 62 are formed on the back surface of the semiconductor substrate 52.

Further, in the fourth embodiment, an optical waveguide 65 is formed between the color filter 61 and the back surface of the semiconductor substrate 52 at a position corresponding to the photodiode PD of each pixel. In more detail, the optical waveguide 65 is formed such that it is buried within an insulating film 66 formed between the back surface of the semiconductor substrate 52 and the color filter 61. The optical waveguide 65 can be of a structure similar to any of those described in the foregoing embodiments. In the fourth embodiment, the optical waveguide 65 has the same structure as that of the optical waveguide 15 according to the first embodiment. More specifically, as illustrated in FIG. 16, the optical waveguide 65 is made up of, when viewed in a cross-section along a horizontal plane, an annular core layer 16 having a higher refractive index than that of a portion surrounding the annular core layer 16, i.e., of the insulating film 66, and a clad layer 17 surrounded by the annular core layer 16 and having a lower refractive index than that of the core layer 16. A flattening film 67 can be formed between the insulating film 66, in which the optical waveguide 65 is formed, and the color filter 61.

The insulating film 66 can be formed of, e.g., a silicon oxide (SiO₂) film having the refractive index of about 1.4. The core layer 16 is preferably formed by coating, e.g., a siloxane-based resin having the refractive index of about 1.7. The clad layer 17 can be formed by using, e.g., a silicon oxide (SiO₂) film having the refractive index of about 1.4.

In the solid-state image sensing device 51 according to the fourth embodiment, incident light L passes through the on-chip lens 62 and enters the photodiode PD from the backside of the semiconductor substrate 52 after being guided by the optical waveguide 65. The incident light L propagates through the interior of the core layer 16 in a similar way to that described above in connection with the optical waveguide 15 in the first embodiment.

Thus, the solid-state image sensing device 51, i.e., the CMOS solid-state image sensing device of backside illumination type, according to the fourth embodiment, includes the optical waveguide 65 that is made up of the annular core layer 16 and the clad layer 17 surrounded by the core layer 16. Because of the optical waveguide 65 having such a structure, it is possible, as in the above-described first embodiment, to prevent the occurrence of cracking inside the optical waveguide 65 and to increase the efficiency of light collection to the photodiode PD.

Further, with the CMOS solid-state image sensing device of backside illumination type according to the fourth embodiment, since the optical waveguide 65 can reduce a component of oblique light, the light can be avoided from entering adjacent pixels, and hence color mixing can be prevented. Consequently, a light-shielding film made of, e.g., tungsten (W) can be omitted.

In addition, since the optical waveguide 65 enables the incident light to reach the photodiode PD with higher efficiency, color mixing can be reduced even when the area occupied by the pixel transistors is reduced in the solid-state image sensing device of backside illumination type, which has a large pixel size. Since the area occupied by the pixel transistors is reduced and the area of the photodiode PD is increased, the sensitivity characteristic of the solid-state image sensing device can be improved.

### Example (1) of Method of Manufacturing Solid-State Image Sensing Device

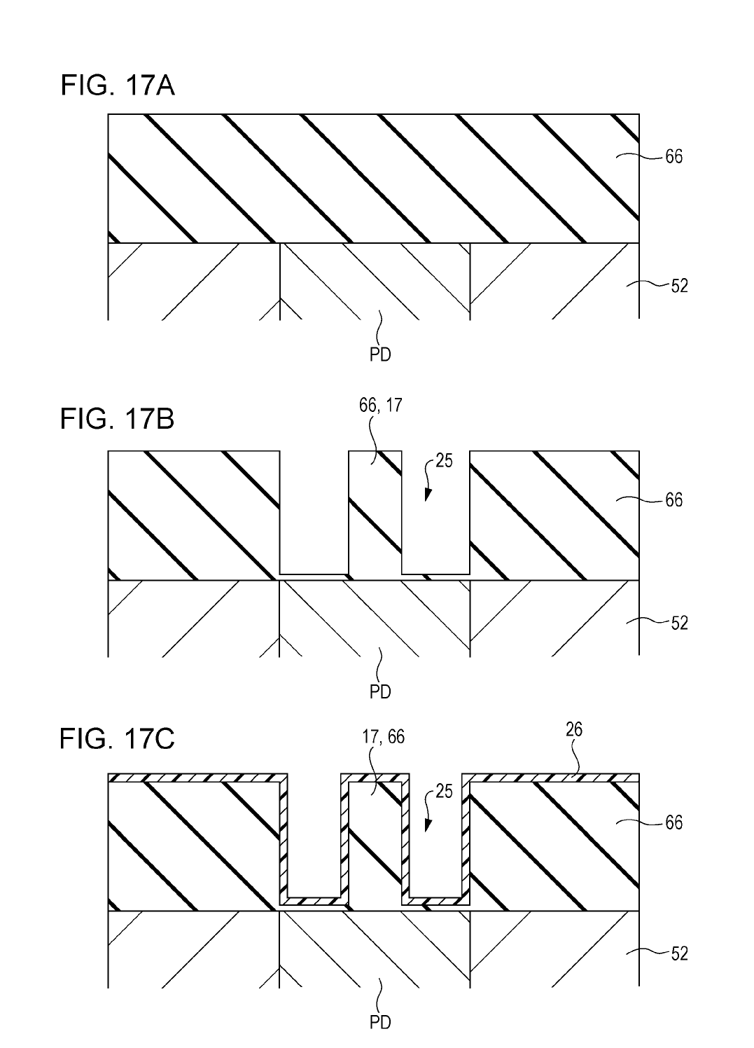

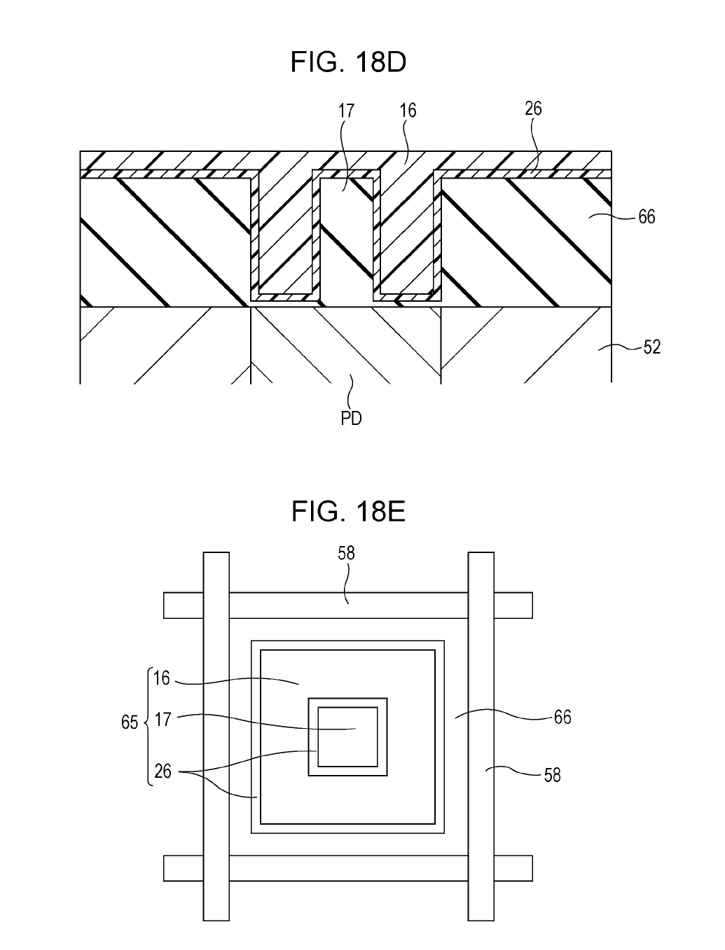

FIGS. 17A to 18E illustrate an example (1) of the method of manufacturing the solid-state image sensing device 51 according to the fourth embodiment. First, the plural pixels each made up of the photodiode PD and the plural pixel transistors, and the element separation region for separating the adjacent pixels from each other are formed in the pixel region of the silicon semiconductor substrate 52. Then, though not shown, the interconnection multilayer 59 including the multiple layers of the interconnection lines 58 with the interlayer insulating film 57 interposed between the adjacent interconnection lines 58 is formed on the front surface of the semiconductor substrate 52. The interconnection multilayer 59 can be formed by the damascene process as described above in the first embodiment. After bonding the support substrate 60 made of, e.g., a silicon substrate onto the interconnection multilayer 59, the semiconductor substrate 52 is polished for thinning from the back surface side by the CMP (Chemical Mechanical Processing), for example, such that the photodiode PD is exposed to the back surface of the semiconductor substrate 52. A p-type semiconductor layer serving to suppress a dark current is formed on the back surface of the semiconductor substrate 52 after the polishing for thinning.

Next, as illustrated in FIG. 17A, the insulating film 66, e.g., the silicon oxide (SiO₂) film having the refractive index of about 1.4, is formed on the back surface of the semiconductor substrate 52 after being polished for thinning. The insulating film 66 serves as a constituent film (that defines an optical path length).

Next, as illustrated in FIG. 17B, the insulating film 66 is patterned in a region corresponding to each photodiode PD to form a pillar-shaped clad layer 17 (made of the insulating film 66) positioned at a center and an annular recess 25 surrounding the clad layer 17. The annular recess 25 is formed such that its bottom surface is positioned as close as possible to the photodiode PD.

Next, as illustrated in FIG. 17C, a passivation film 26 is formed all over an inner wall surface of the annular recess 25, an upper surface of the clad layer 17, and an upper surface of the insulating film 66. The passivation film 26 is made compatible with a siloxane-based resin, which is used to form the core layer later, to ensure satisfactory adhesion of the core layer with respect to the inner surface of the annular recess 25. The passivation film 26 constitutes a part of the core layer, and it is made of, e.g., a silicon nitride (SiN) film having the refractive index of about 2.0, which is higher than that of the core layer.

Next, as illustrated in FIG. 18D, the siloxane-based resin, for example, is coated all over the clad layer 17 and the insulating film 66, including an inner space of the annular recess 25. The core layer 16 having an annular shape is formed by the siloxane-based resin that has been filled in the annular recess 25.

Through the above-described steps, as illustrated in FIG. 18E, the optical waveguide 65 is formed which is made up of, when viewed in a cross-section along a horizontal plane, the pillar-shaped clad layer 17 positioned at the center and the annular core layer 16 surrounding the clad layer 17. Further, the optical waveguide 65 of this example includes the passivation film 26, which is formed along outer and inner peripheries of the core layer 16, which constitutes a part of the core layer 16, and which has a higher refractive index than the core layer 16.

Thereafter, the color filter and the on-chip lens are formed on the flattened siloxane-based resin layer, whereby the CMOS solid-state image sensing device 51 of backside illumination type, including the optical waveguide 65, is obtained.

### Example (2) of Method of Manufacturing Solid-State Image Sensing Device

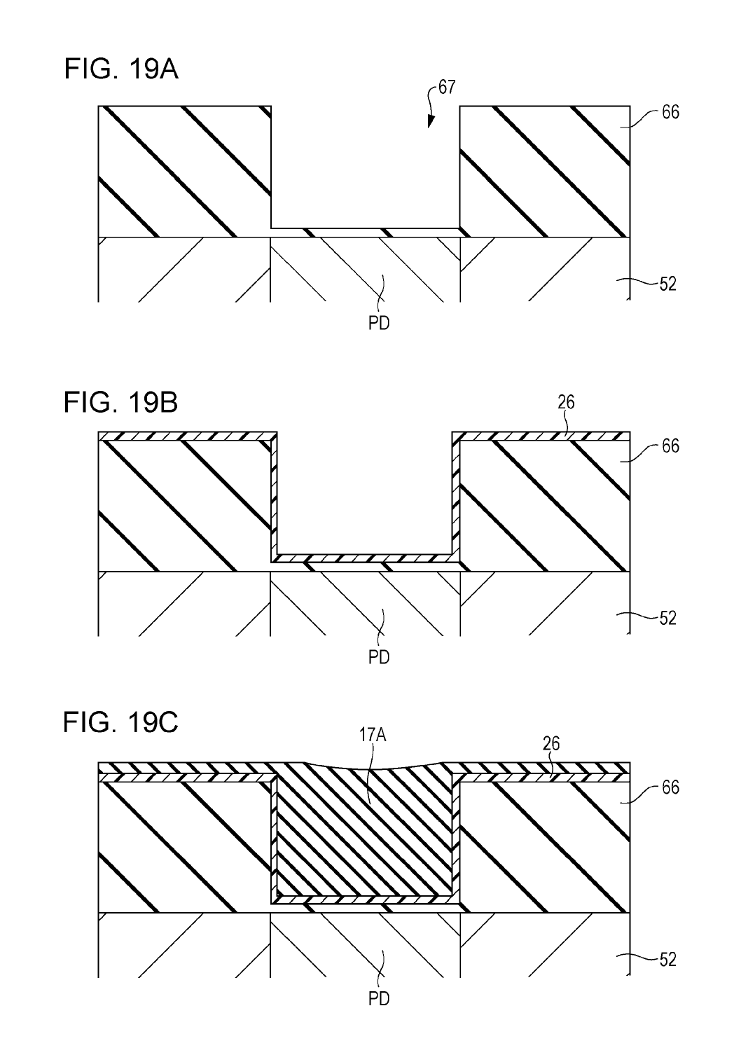

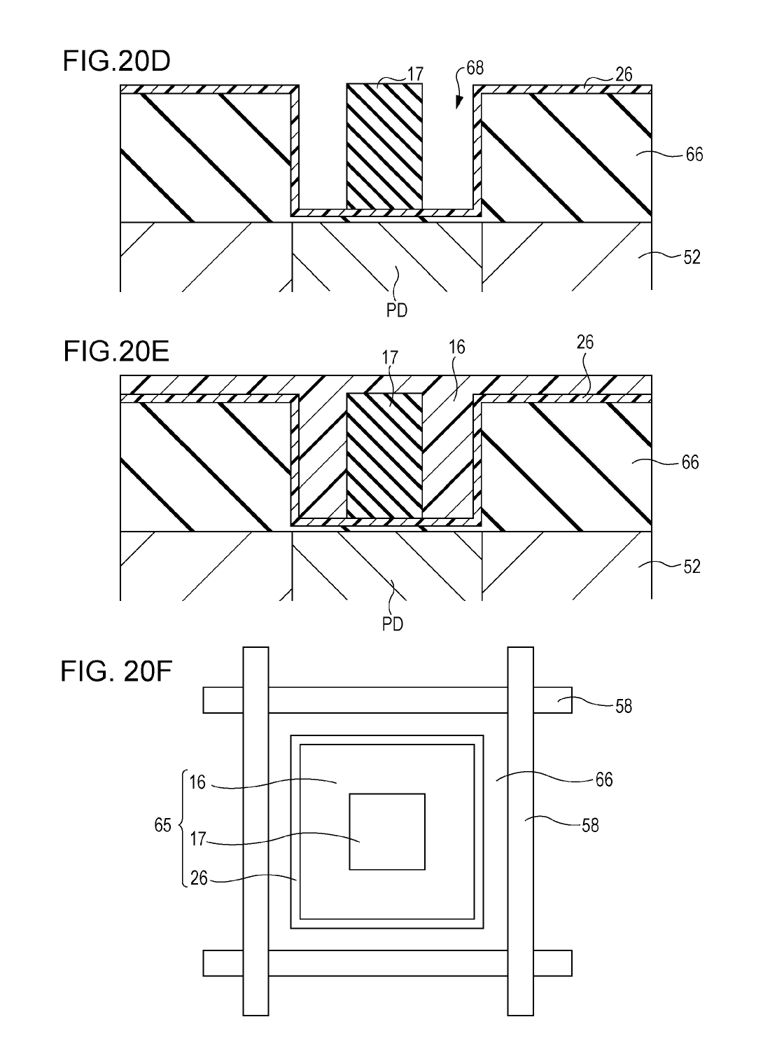

FIGS. 19A to 20F illustrate an example (2) of the method of manufacturing the solid-state image sensing device 51 according to the fourth embodiment. First, as in the above-described example (1), the plural pixels each made up of the photodiode PD and the plural pixel transistors, and the element separation region for separating the adjacent pixels from each other are formed in the pixel region of the silicon semiconductor substrate 52. Then, though not shown, the interconnection multilayer 59 including the multiple layers of the interconnection lines 58 with the interlayer insulating film 57 interposed between the adjacent interconnection lines 58 is formed on the front surface of the semiconductor substrate 52. The interconnection multilayer 59 can be formed by the damascene process as described above in the first embodiment. After bonding the support substrate 60 made of, e.g., a silicon substrate onto the interconnection multilayer 59, the semiconductor substrate 52 is polished for thinning from the back surface side by the CMP (Chemical Mechanical Processing), for example, such that the photodiode PD is exposed to the back surface of the semiconductor substrate 52. A p-type semiconductor layer serving to suppress a dark current is formed on the back surface of the semiconductor substrate 52 after the polishing for thinning.

Next, as illustrated in FIG. 19A, the insulating film 66, e.g., the silicon oxide film having the refractive index of about 1.4, is formed on the back surface of the semiconductor substrate 52 after being polished for thinning. Then, the insulating film 66 is selectively etched away in its portion corresponding to each of the photodiodes PD, thereby forming a recess 67. The recess 67 is formed such that its bottom surface is positioned as close as possible to the photodiode PD.

Next, as illustrated in FIG. 19B, a passivation film 26 made of, e.g., a silicon nitride (SiN) film having the refractive index of about 2.0 is formed all over an inner wall surface of the recess 67 and a surface of the insulating film 66.

Next, as illustrated in FIG. 19C, for example, a silicon oxide (SiO₂) film 17A having the refractive index of about 1.4 and becoming the clad layer is deposited on the passivation film 26 so as to fill the recess 67. The silicon oxide film 17A can be formed, for example, by the CVD (Chemical Vapor Deposition) process.

Next, as illustrated in FIG. 20D, the silicon oxide film 17A is patterned by using the photolithography technique and the etching technique to form the clad layer 17 at a center in the recess 67 such that an upper surface of the clad layer 17 is flush with an upper surface of the passivation film 26 on the insulating film 66. With the formation of the clad layer 17, an annular recess 68 is formed within the recess 67 in a surrounding relation to the clad layer 17. Stated another way, the clad layer 17 surrounded by the annular recess 68 is formed within the recess 67 when viewed in a cross-section along a horizontal plane.

Next, as illustrated in FIG. 20E, the siloxane-based resin, for example, is coated all over the clad layer 17 and the insulating film 66, including an inner space of the annular recess 68. The core layer 16 having an annular shape is formed by the siloxane-based resin that has been filled in the annular recess 68.

Through the above-described steps, as illustrated in FIG. 20F, the optical waveguide 65 is formed which is made up of, when viewed in a cross-section along a horizontal plane, the pillar-shaped clad layer 17 positioned at a center and the annular core layer 16 surrounding the clad layer 17. Further, the optical waveguide 65 of this example includes the passivation film 26, which is formed along an outer periphery of the core layer 16, which constitutes a part of the core layer 16, and which has a higher refractive index than the core layer 16.

Thereafter, the color filter and the on-chip lens are formed on the flattened siloxane-based resin layer, whereby the CMOS solid-state image sensing device 51 of backside illumination type, including the optical waveguide 65, is obtained.

With the above-described examples (1) to (2) of the method of manufacturing the solid-state image sensing device 51, it is possible to manufacture the solid-state image sensing device 51 including the optical waveguide 65 of such a basic structure that the annular core layer 16 is formed in a surrounding relation to the pillar-shaped clad layer 17 at the center. Further, since the siloxane-based resin becoming the core layer 16 is filled in the annular recess 68 after forming the passivation film 26 made of the silicon nitride film on the inner wall surface of the annular recess 68, adhesion of the core layer 16 in the annular recess 25 with respect to the inner wall surface of the annular recess 68 is obtained at a satisfactory level.

### 6. Fifth Embodiment

### Example of Structure of Solid-State Image Sensing Device

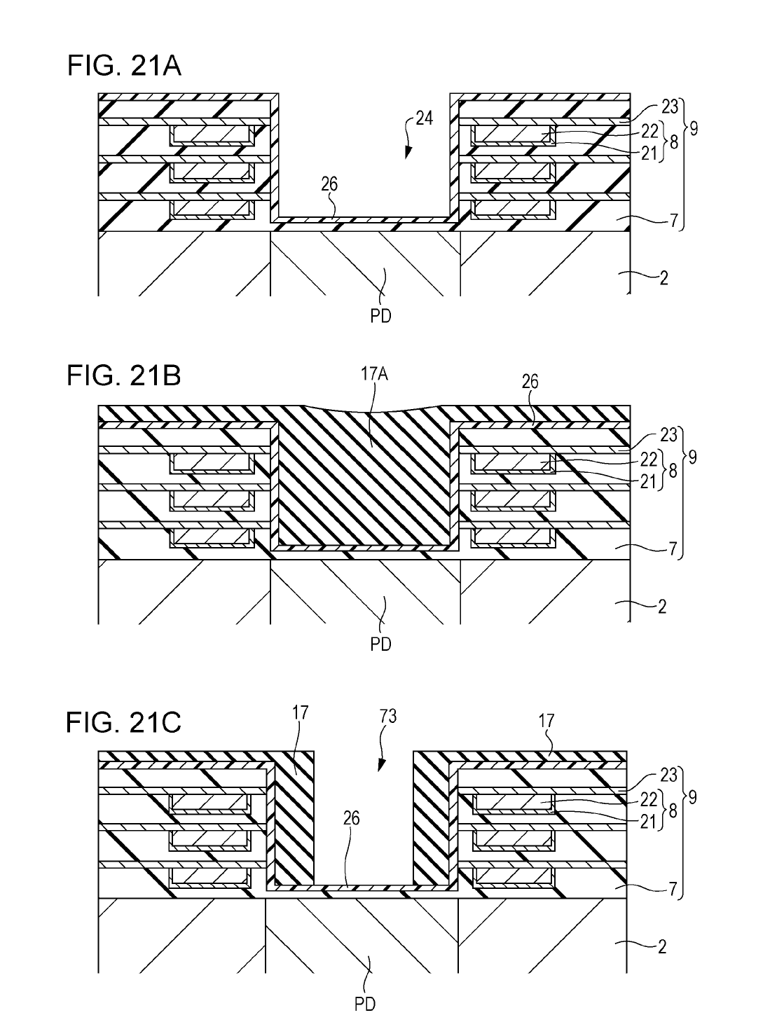

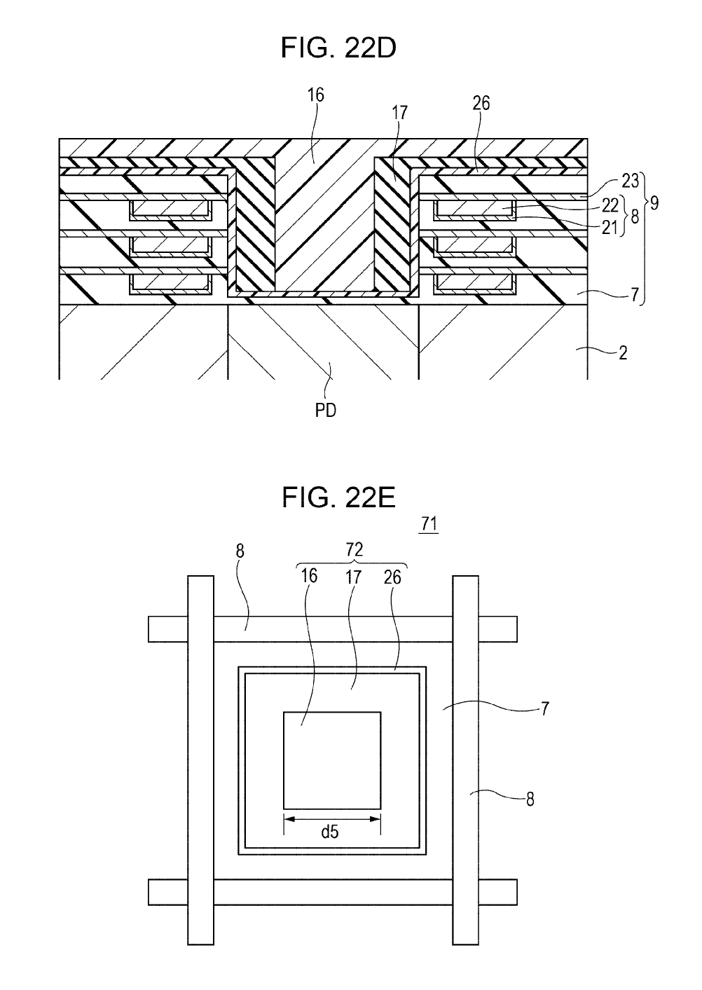

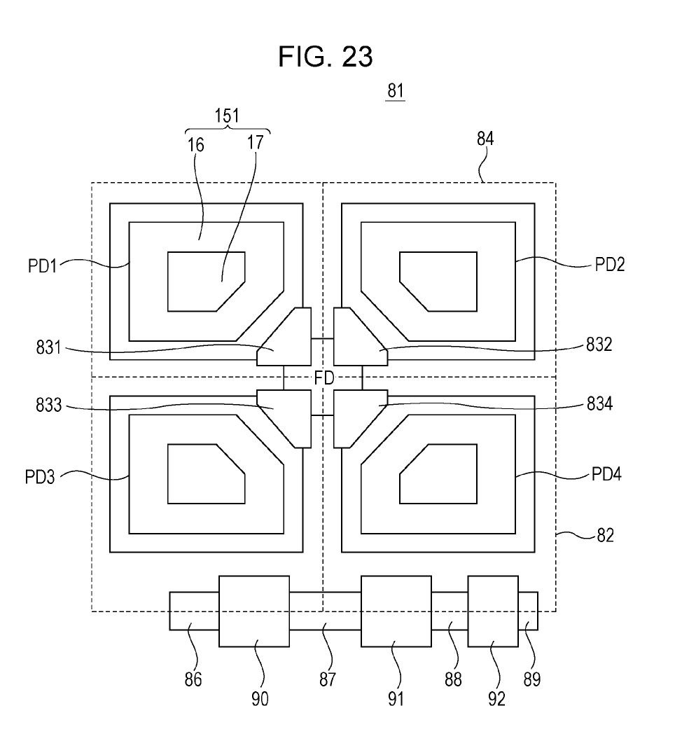

A solid-state image sensing device according to a fifth embodiment of the present technology will be described. FIGS. 21A to 22E illustrate a CMOS solid-state image sensing device 71 of front-side illumination type according to the fifth embodiment, in particular, an optical waveguide 72 for use therein, along with a method of manufacturing the solid-state image sensing device. The solid-state image sensing device 71 according to the fifth embodiment includes the optical waveguide 72, illustrated in FIG. 22E, which is formed on the photodiode PD of each pixel. The optical waveguide 72 is buried in an interlayer insulating film 7 of an interconnection multilayer 9, and it is made up of an annular passivation film 26 serving as an annular core layer, a clad layer 17 surrounded by the passivation film 26, and a pillar-shaped core layer 16 positioned at a center and surrounded the clad layer 17.

Because the remaining structure is similar to that described above in connection with the first embodiment, duplicate description of the remaining structure is omitted.

### [Method of Manufacturing Solid-State Image Sensing Device]

In the following description of the method of manufacturing the solid-state image sensing device according to the fifth embodiment, components corresponding to those in the manufacturing method described above in the first embodiment are denoted by the same reference symbols.

In the fifth embodiment, as in the above-described step illustrated in FIG. 3A, the pixel made up of the photodiode PD and the pixel transistors, and the element separation region are formed in a silicon semiconductor substrate 2. Thereafter, the interconnection multilayer 9 including the multiple layers of the interconnection lines 8 with an interlayer insulating film 7 interposed between the adjacent interconnection lines 8 is formed on the surface of the semiconductor substrate 2 by the damascene process.

Next, as illustrated in FIG. 21A, the interlayer insulating film 7 and a diffusion prevention film 23 are selectively etched away in a portion of the interconnection multilayer 9 corresponding to each of the photodiodes PD, thereby forming a recess 24 substantially in the interlayer insulating film 7. The recess 24 is formed such that its bottom surface is positioned as close as possible to the photodiode PD. Then, a passivation film 26 becoming the annular core layer and made of, e.g., a silicon nitride (SiN) film having the refractive index of about 2.0 is formed all over an inner wall surface of the recess 24 and a surface of the interconnection multilayer 9.

Next, as illustrated in FIG. 21B, a silicon oxide (SiO₂) film 17A having the refractive index of about 1.4 and becoming the clad layer is deposited on the passivation film 26 so as to fill the recess 24. The silicon oxide film 17A can be formed, for example, by the CVD (Chemical Vapor Deposition) process.

Next, as illustrated in FIG. 21C, an upper surface of the silicon oxide film 17A is flattened and the silicon oxide film 17A is selectively etched away in a central area of the recess 24, thereby forming a central recess 73. With the formation of the central recess 73, the clad layer 17 is formed by the silicon oxide film 17A that is left between the central recess 73 and the annular passivation film 26 surrounding the central recess 73.

Next, as illustrated in FIG. 22D, the siloxane-based resin, for example, is coated all over the clad layer 17 so as to fill the central recess 73. The core layer 16 having a pillar-like shape is formed by the siloxane-based resin that has been filled in the central recess 73.

Through the above-described steps, as illustrated in FIG. 22E, the optical waveguide 72 is formed which is made up of, when viewed in a cross-section along a horizontal plane, the core layer 16 positioned at a center, the clad layer 17 surrounding the core layer 16, and the annular passivation film 26 surrounding the clad layer 17 and serving as the annular core layer.

Thereafter, the color filter and the on-chip lens are formed on the flattened siloxane-based resin layer, whereby the CMOS solid-state image sensing device 71 of front-side illumination type, including the optical waveguide 72, is obtained. Be it noted that the optical waveguide 72 is applicable to the CMOS solid-state image sensing device of backside illumination type as well.

With the solid-state image sensing device 71 according to the fifth embodiment, the optical waveguide 72 is made up of the passivation film 26 serving as the annular core layer, the clad layer 17 surrounded by the passivation film 26, and the core layer 16 positioned at the center of the clad layer 17. Thus, since the core layer 16 made of, e.g., the siloxane-based resin is formed at the center of the clad layer 17, an opening width d5 of the core layer 16 can be so reduced as to prevent the occurrence of cracking between the core layer 16 and the clad layer 17 with thermal expansion. The optical waveguide 72 according to the fifth embodiment is preferably applied, in particular, to an optical waveguide for use in a solid-state image sensing device having a large pixel size. Further, since the optical waveguide 72 has reflection interfaces between the passivation film 26 and the clad layer 17 and between the clad layer 17 and the core layer 16, the number of reflection interfaces is increased. Consequently, as in the above-described embodiments, a light loss can be reduced and the efficiency of light collection to the photodiode PD can be increased.

### 7. Sixth Embodiment

### Example of Structure of Solid-State Image Sensing Device

FIG. 23 illustrates the solid-state image sensing device according to the sixth embodiment of the present technology. The sixth embodiment represents an application to a CMOS solid-state image sensing device of front-side illumination type in which the so-called 4-pixel sharing units, each including 2 pixels in the horizontal direction and 2 pixels in the vertical direction, are two-dimensionally arrayed. In the solid-state image sensing device 81 according to the sixth embodiment, as illustrated in FIG. 23, a pixel region is formed by two-dimensionally arraying 4-pixel sharing units 82, each including a (2×2) array of photodiodes PD (PD1 to PD4) corresponding to four pixels. Four photodiodes PD in each 4-pixel sharing unit 82 share one group of pixel transistors other than transfer transistors. More specifically, in each 4-pixel sharing unit 82, the four photodiodes PD1 to PD4 share one floating diffusion FD. The pixel transistors are made up of four transfer transistors Tr1 (Tr11 to Tr14), one reset transistor Tr2 (86, 87, 90), one amplification transistor Tr3 (87, 88, 91), and one selection transistor Tr4 (88, 89, 92), the latter three transistors being shared by the four photodiodes. While the pixel transistors are constituted by four transistors in the sixth embodiment, the pixel transistors may be constituted by three transistors.

The floating diffusion FD is arranged at a center surrounded by the four photodiodes PD1 to PD4. The transfer transistors Tr11 to Tr14 include respective transfer gate electrodes 83 (831 to 834) arranged between the floating diffusion FD, which is shared by the transfer transistors, and the corresponding photodiodes PD1 to PD4.

One pixel corresponds to a region 84, which includes one of the photodiodes PD and which is surrounded by a vertical line and a horizontal line both passing a center of the floating diffusion FD, a horizontal line passing a center of a region where the pixel transistors are formed, and a vertical line each passing a midpoint between the 4-pixel sharing units adjacent to each other in the horizontal direction.

The reset transistor Tr2 is formed by a pair of source and drain regions 86, 87 and a reset gate electrode 90. The amplification transistor Tr3 is formed by a pair of source and drain regions 87, 88 and an amplification gate electrode 91. The selection transistor Tr4 is formed by a pair of source and drain regions 88, 89 and a selection gate electrode 92.

The floating diffusion FD and the source and drain regions 86 to 89 are formed as semiconductor regions of first conductivity type. In the sixth embodiment, because electrons serve as signal charges, the floating diffusion FD and the source and drain regions 86 to 89 are formed as n-type semiconductor regions.

Further, in the sixth embodiment, the optical waveguide 151 having a polygonal shape in a horizontal cross-section, illustrated in FIG. 14A, is formed on each of the photodiodes PD (PD1 to PD4). The optical waveguide 151 is formed in match with the shape of the corresponding photodiode PD, and it includes the annular core layer 16 made of, e.g., the siloxane-based resin and the clad layer 17 surrounded by the core layer 16 and made of, e.g., the silicon oxide film. Though not illustrated, the optical waveguide 151 is formed in the interlayer insulating film of the interconnection multilayer between the color filter and the photodiode PD such that a light emergent end of the optical waveguide 151 is positioned close to the photodiode PD.

With the solid-state image sensing device 81 according to the sixth embodiment, since the solid-state image sensing device 81 includes the optical waveguide 151 made up of the annular core layer 16 and the clad layer 27 at the center, it is possible, as in the above-described embodiment, to prevent the occurrence of cracking due to thermal expansion inside the optical waveguide and to increase the efficiency of light collection to the photodiode PD.

The above-described optical waveguides 152 and 153 illustrated in FIGS. 14B and 14C, respectively, and the above-described optical waveguide 72 according to the fifth embodiment can also be applied to the above-described solid-state image sensing device of backside illumination type.

While the solid-state image sensing devices including the optical waveguides according to the embodiments of the present technology are applied to a CMOS solid-state image sensing device, they can also be applied to a CCD solid-state image sensing device. The CCD solid-state image sensing device includes, as described above, a plurality of photoelectric conversion regions (photodiodes) serving as light receiving portions, a vertical transfer register arranged for each column of the light receiving portions, a horizontal transfer register, and an output portion. Each pixel is made up of the photoelectric conversion region and a device to read signal charges from the photoelectric conversion region, i.e., a transfer portion of the vertical transfer register corresponding to the photoelectric conversion region. Further, the optical waveguide illustrated in any of the above-described embodiments is formed in the photoelectric conversion region for each pixel.

In the solid-state image sensing device according to each of the above-described embodiments, the signal charges are electrons, the first conductivity type is n-type, and the second conductivity type is p-type. However, embodiments of the present technology are also applicable to a solid-state image sensing device in which the signal charges are holes. In such a case, the second conductivity type is n-type, and the first conductivity type is p-type.

### 8. Seventh Embodiment

### Example of Configuration of Electronic Apparatus

The solid-state image sensing device according to the above-described embodiment of the present technology can be applied to electronic apparatuses including a camera system such as a digital camera or a video camera, a cellular phone with the image sensing function, and other types of apparatuses with the image sensing function.

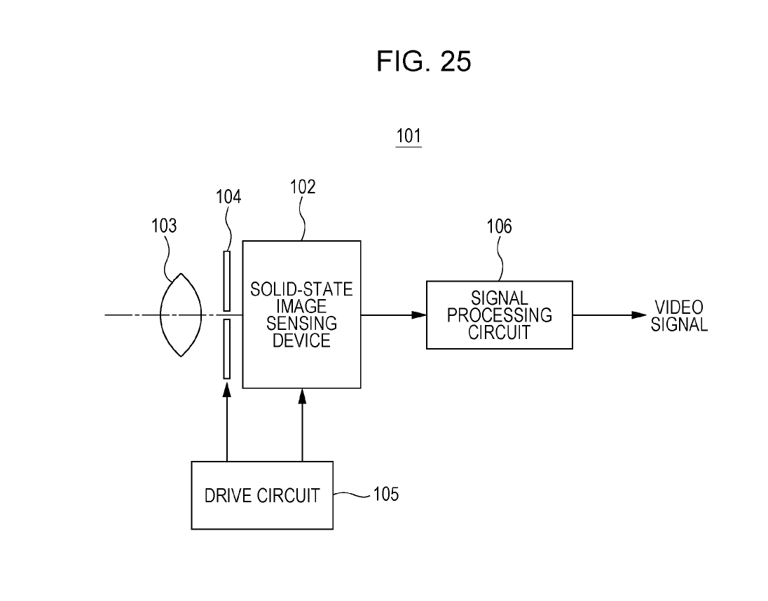

FIG. 25 illustrates the seventh embodiment of the present technology in which the embodiment is applied to a camera as one example of the electronic apparatuses. The camera according to the seventh embodiment is, for example, a video camera capable of taking a still image and a moving image. The camera 101 according to the seventh embodiment includes a solid-state image sensing device 102, an optical system 103 for introducing incident light to a light-receiving sensor portion of the solid-state image sensing device 102, a shutter device 104, a drive circuit 105 for driving the solid-state image sensing device 102, and a signal processing circuit 106 for processing an output signal of the solid-state image sensing device 102.

One of the solid-state image sensing devices according to the above-described embodiments can be employed as the solid-state image sensing device 102. The optical system (optical lens) 103 focuses image light (incident light) from a subject onto an image sensing surface of the solid-state image sensing device 102. Signal charges are thereby accumulated in the solid-state image sensing device 102 for a certain period. The optical system 103 may be an optical lens system constituted by a plurality of optical lenses. The shutter device 104 controls a light illumination period and a light-shield period with respect to the solid-state image sensing device 102. The drive circuit 105 supplies a drive signal for controlling the transfer operation of the solid-state image sensing device 102 and the shutter operation of the shutter device 104. Signal transfer in the solid-state image sensing device 102 is performed in accordance with a drive signal (timing signal) supplied from the drive circuit 105. The signal processing circuit 106 executes various types of signal processing. A video signal obtained through the signal processing is stored in a storage medium, e.g., a memory, or it is output to a monitor.

With the electronic apparatus according to the seventh embodiment, it is possible, in the solid-state image sensing device including the optical waveguide, to prevent the occurrence of cracking due to thermal expansion inside the optical waveguide and to increase the efficiency of light collection to the photodiode. As a result, the electronic apparatus having high quality can be provided. For example, a high-quality camera, etc. can be provided.

The present disclosure contains subject matter related to that disclosed in Japanese Priority Patent Application JP 2010-179196 filed in the Japan Patent Office on Aug. 10, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state image sensing device comprising:
a plurality of pixels each made up of a photoelectric conversion region and means for reading signal charges from the photoelectric conversion region; and
an optical waveguide formed corresponding to the photoelectric conversion region of each pixel,
wherein, when viewed in a cross-section along a horizontal plane, the optical waveguide includes an annular core layer having a higher refractive index than a portion surrounding the annular core layer, and
a clad layer surrounded by the annular core layer and having a lower refractive index than the annular core layer.

2. The solid-state image sensing device according to claim 1, wherein, when viewed in the cross-section along the horizontal plane, the optical waveguide further includes a second core layer positioned at a center of the clad layer and having a higher refractive index than the clad layer.

3. The solid-state image sensing device according to claim 1, wherein, when viewed in the cross-section along the horizontal plane, the optical waveguide further includes a passivation film which is positioned along an outer periphery and/or an inner periphery of the core layer, which has a higher refractive index than the core layer, and which constitutes a part of the core layer.

4. The solid-state image sensing device according to claim 1, wherein the core layer is a siloxane-based resin, and
the clad layer is a silicon oxide film.

5. The solid-state image sensing device according to claim 3, wherein the core layer is a siloxane-based resin,
the clad layer is a silicon oxide film, and
the passivation film is a silicon nitride film.

6. The solid-state image sensing device according to claim 2, wherein the annular core layer is formed of a passivation film made of a silicon nitride film,
the clad layer is formed of a silicon oxide film, and
the second core layer at the center of the clad layer is formed of a siloxane-based resin.

7. The solid-state image sensing device according to claim 1, wherein the pixel is made up of the photoelectric conversion region and pixel transistors, and
the optical waveguide is formed in an insulating film formed on a light-incident back surface of a semiconductor substrate in which the pixel is formed.

8. The solid-state image sensing device according to claim 1, wherein the pixel is made up of the photoelectric conversion region and pixel transistors, and
the optical waveguide is formed in an interlayer insulating film of an interconnection multilayer that is formed on a light-incident front surface of a semiconductor substrate in which the pixel is formed.

9. A method of manufacturing a solid-state image sensing device, the method comprising:
forming, on a semiconductor substrate, a plurality of pixels each made up of a photoelectric conversion region and means for reading signal charges from the photoelectric conversion region;
forming a recess in a portion of a constituent film formed on one surface of the semiconductor substrate, which portion corresponds to the photoelectric conversion region of each pixel;
forming, in the recess, a clad layer that is surrounded by an annular recess when viewed in a cross-section along a horizontal plane; and
filling, in the annular recess, a core layer having a higher refractive index than the constituent film present as an outer surrounding portion and than the clad layer,
thereby forming an optical waveguide made up of the annular core layer and the clad layer.

10. The method of manufacturing the solid-state image sensing device according to claim 9, the method further comprising:
forming, in addition to the annular recess, a central recess positioned at a center of the clad layer, and
filling the core layer in each of the annular recess and the central recess.

11. The method of manufacturing the solid-state image sensing device according to claim 9, the method further comprising:
forming, when viewed in the cross-section along the horizontal plane, a passivation film which is positioned along an outer periphery and/or an inner periphery of the core layer, which has a higher refractive index than the core layer, and which constitutes a part of the core layer.

12. The method of manufacturing the solid-state image sensing device according to claim 9, the method further comprising:
forming the core layer by using a siloxane-based resin, and
forming the clad layer as a silicon oxide film.

13. The method of manufacturing the solid-state image sensing device according to claim 11, the method further comprising:
forming the core layer by using a siloxane-based resin,
forming the clad layer as a silicon oxide film, and
forming the passivation film as a silicon nitride film.

14. The method of manufacturing the solid-state image sensing device according to claim 9, the method further comprising:
forming the pixel made up of the photoelectric conversion region and pixel transistors, and
forming the optical waveguide in an insulating film formed on a light-incident back surface of the semiconductor substrate.

15. The method of manufacturing the solid-state image sensing device according to claim 9, the method further comprising:
forming the pixel made up of the photoelectric conversion region and pixel transistors, and
forming the optical waveguide in an interlayer insulating film of an interconnection multilayer formed on a light-incident front surface of the semiconductor substrate.

16. An electronic apparatus comprising:
a solid-state image sensing device;
an optical system for introducing incident light to a photoelectric conversion region of the solid-state image sensing device; and
a signal processing circuit for processing an output signal of the solid-state image sensing device,
wherein the solid-state image sensing device is constituted as the solid-state image sensing device according to claim 1.
